(19) United States
(12) Patent Application Publication
(10) Pub. No.: US 2010/0234478 A1
(43) Pub. Date: Sep. 16, 2010

(54) PROCESS FOR PREPARATION OF CONDUCTING POLYMERS

(75) Inventor: Reuben D. Rieke, Lincoln, NE (US)

Correspondence Address: OBLON, SPIVAK, MCCLELLAND MAIER & NEUSTADT, L.L.P., 1940 DUKE STREET, ALEXANDRIA, VA, 22314, US

(73) Assignees: BASE SE, Ludwigshafen (DE); RIEKE METALS, INC., Lincoln, NE (US)

(21) Appl. No.: 12/740,353

(22) PCT Filed: Oct. 29, 2007
(86) PCT No.: PCT/US07/22925

§ 371 Date: Apr. 29, 2010

(51) Int. Cl. B01J 41/12

(52) U.S. Cl. 521/25

(57) ABSTRACT

Methods of preparing conducting polymers and the conductive polymers prepared therefrom are provided. The method includes a) combining a monomer-metal complex together with a manganese (II) halide to provide a monomer-manganese complex, and b) combining the monomer-manganese complex together with a metal catalyst to provide the conductive polymer. Electronic devices can be made using the polymers prepared as described herein.

### FIELD OF INVENTION

The invention relates to an improved process for making conductive polymers having high regioselectivity in a more efficient and less costly manner.

### BACKGROUND OF THE INVENTION

Conductive polymers have received significant attention recently due to their nonlinear optical properties, electro-conductivity, and other valuable properties. They can be employed in electrical components such as transistors, diodes, triodes, and rectifiers in a variety of applications. The use of conductive polymers for these and other applications has often been hampered by irregular conductivity due a lack of purity.

There are several known synthetic methods for preparing regioregular conductive polymers. These known techniques, however, often provide substituted conductive polymers that have a less than optimal regioregularity. Highly regioregular conductive polymers are desired because monomer orientation has a great influence on the electro-conductivity of the polymer. A highly regioregular conductive polymer allows for improved packing and optimized microstructure, leading to improved charge carrier mobility.

Accordingly, there remains a need for improved synthetic methods for high purity and highly regioregular conductive polymers. Also needed are devices with high purity regioregular conductive polymer components for improved ease of manufacture and device operation.

### SUMMARY OF THE INVENTION

The present invention provides methods of preparing conducting polymers and the resulting polymers prepared thereby. In these methods, dihalo-monomers are combined together with organometallic reagents to provide monomer-metal complexes. Next, the monomer-metal complexes are combined together with a manganese (II) halide to provide monomer-manganese complexes. Finally, the monomer-manganese complexes are combined together with metal catalysts to afford conducting polymers.

One advantage of these methods is that transmetallation of the monomer-metal complex with manganese allows for polymerization at a lower temperature than many known methods. Another advantage is that the methods described herein produce polymers of greater regioregularity (higher percentage of head-to tail monomer linkages) with lower catalyst loadings.

The conducting polymers may be, for example, regioregular and regiorandom conducting polymers and block copolymers. Regioregular conducting polymers and block copolymers can be provided, for example, through use of a nickel (II) catalyst to accomplish the polymerization. Alternatively, regiorandom conducting polymers and block copolymers can be provided, for example, through use of a palladium (0) catalyst to accomplish the polymerization.

The conducting polymers may be, for example, unsubstituted or substituted homopolymers, unsubstituted or substituted random copolymers, or unsubstituted or substituted block copolymers depending upon the reactants and the reaction sequence. For example, aromatic homopolymers, random copolymers, and block copolymers may be prepared from one or more aromatic monomers, respectively. Heteroaromatic homopolymers, random copolymers, and block copolymers may be prepared, for example, from heteroaromatic monomers. Further, combinations of aromatic and heteroaromatic monomers may also be used, for example, to prepare random copolymers and block copolymers.

Preferably, the conducting polymers are, for example, unsubstituted or substituted polythiophene homopolymers, poly(3-substituted-thiophene) homopolymers, poly(3-substituted-thiophene) copolymers, poly(3,4-disubstituted-thiophene) homopolymers, poly(3,4-disubstituted-thiophene) copolymers, copolymers including unsubstituted thiophene, 3-substituted-thiophene, 3,4-disubstituted-thiophene, or a combination thereof, polythiophene block copolymers including unsubstituted thiophene, 3-substituted-thiophene, 3,4-disubstituted-thiophene, or a combination thereof, or block copolymers including a block of polythiophene and a block of another aromatic or heteroaromatic conducting polymer.

The conducting polymers have superior electroconductive properties. The conducting polymers are characterized by their monomeric composition, their degree of regioregularity, and their physical properties such as molecular weight and number average molecular weight, polydispersity, conductivity, purity obtained directly from its preparatory features, as well as other properties. The conducting polymers are characterized as well by the process for their preparation.

The present invention is also directed to thin films of regioregular and regiorandom conducting polymers prepared by the methods described herein. The regioregular and regiorandom conducting polymers films may include, for example, a dopant.

The present invention also provides an electronic device including a circuit constructed with the conducting polymers prepared by any of the methods described herein. The electronic device may be a thin film transistor, a field effect transistor, a radio frequency identification tag, a flat panel display, a photovoltaic device, an electroluminescent display device, a sensor device, and electrophotographic device, or an organic light emitting diode (OLED).

The present invention provides a method of preparing a conductive polymer including: a) combining a first monomer-metal complex and an optional second monomer-metal complex together with a manganese (II) halide to provide a monomer-manganese complex, wherein each monomer-metal complex is prepared by combining a dihalo-monomer together with an organometallic reagent; and b) combining the monomer-manganese complex together with a metal catalyst to provide the conductive polymer, wherein each dihalo-monomer is independently an aromatic or heteroaromatic group substituted by two halogens wherein the halogens are the same or different, and wherein halogen is F, Cl, Br, or I.

In one embodiment, the organometallic reagent is a Grignard reagent, a Grignard-ate complex, an alkyl lithium reagent, an alkyl lithium cuprate, an alkyl aluminum reagent, or an organozinc reagent, wherein the organozinc reagent is RZnX, R₂ZnX, or R₃ZnM, wherein R is (C₂-C₁₂) alkyl, M is magnesium, manganese, lithium, sodium, or potassium, and X is F, Cl, Br, or I. In another embodiment, the metal catalyst and the monomer-manganese complex are combined in any order to provide the conducting polymer. In yet another embodiment, the aromatic or heteroaromatic group may be benzene, thiophene, pyrrole, furan, aniline, phenylene vinylene, thienylene vinylene, bis-thienylene vinylene, acetylene, fluorene, arylene, isothianaphthalene, p-phenylene sulfide, thieno[2,3-b]thiophene, thieno[2,3-c]thiophene, thieno[2,3-d]thiophene, naphthalene, benzo[2,3]thiophene, benzo[3,4]thiophene, biphenyl, or bithiophenyl, and wherein the aromatic or heteroaromatic group has from zero to about three substituents other than halogen.

In one embodiment, the substituents of the foregoing aromatic or heteroaromatic group are each independently (C₁-C₂₄)alkyl, (C₁-C₂₄)alkylthio, (C₁-C₂₄)alkylsilyl, or (C₁-C₂₄)alkoxy that may be optionally substituted with about one to about five ester, ketone, nitrile, amino, aryl, heteroaryl, or heterocyclyl groups, and one or more carbon atoms of the alkyl chain of the alkyl group may be optionally exchanged by about one to about ten O, S, or NH groups, and wherein the conducting polymer is a regioregular homopolymer, a regiorandom homopolymer, a regioregular copolymer, or a regiorandom copolymer.

In another embodiment, the first dihalo-monomer and the optional second dihalo-monomer are each independently selected from the group consisting of a 2,5-dihalo-thiophene, a 2,5-dihalo-pyrrole, a 2,5-dihalo-furan, a 1,3-dihalobenzene, a 2,5-dihalo-3-substituted-thiophene, a 2,5-dihalo-3-substituted-pyrrole, a 2,5-dihalo-3-substituted-furan, a 1,3-dihalo-2-substituted-benzene, a 1,3-dihalo-4-substituted-benzene, a 1,3-dihalo-5-substituted-benzene, a 1,3-dihalo-6-substituted-benzene, a 1,3-dihalo-2,4-disubstituted-benzene, a 1,3-dihalo-2,5-disubstituted-benzene, a 1,3-dihalo-2,6-disubstituted-benzene, a 1,3-dihalo-4,5-disubstituted-benzene, a 1,3-dihalo-4,6-disubstituted-benzene, a 1,3-dihalo-2,4,5-trisubstituted-benzene, a 1,3-dihalo-2,4,6-trisubstituted-benzene, a 1,3-dihalo-2,5,6-trisubstituted-benzene, a 1,4-dihalo-2-substituted-benzene, a 1,4-dihalo-3-substituted-benzene, a 1,4-dihalo-5-substituted-benzene, a 1,4-dihalo-6-substituted-benzene, a 1,4-dihalo-2,3-disubstituted-benzene, a 1,4-dihalo-2,5-disubstituted-benzene, a 1,4-dihalo-2,6-disubstituted-benzene, a 1,4-dihalo-3,5-disubstituted-benzene, a 1,4-dihalo-3,6-disubstituted-benzene, a 1,4-dihalo-3,5,6-trisubstituted-benzene, a 2,5-dihalo-3,4-disubstituted-thiophene, a 2,5-dihalo-3,4-disubstituted-pyrrole, a 2,5-dihalo-3,4-disubstituted-furan, and a combination thereof.

In yet another embodiment, the conducting polymer is an unsubstituted polythiophene homopolymer, a poly(3-substituted-thiophene) homopolymer, a poly(3-substituted-thiophene) copolymer, a poly(3,4-disubstituted-thiophene) homopolymer, a poly(3,4-disubstituted-thiophene) copolymer, or a copolymer including unsubstituted thiophene, 3-substituted-thiophene, 3,4-disubstituted-thiophene, or a combination thereof.

In one embodiment, the manganese (II) halide is manganese fluoride, manganese chloride, manganese bromide, manganese iodide, or a combination thereof.

In another embodiment, the metal catalyst is a nickel (II) catalyst, wherein the nickel (II) catalyst is or is derived from Ni(dppe)Cl₂, Ni(dppp)Cl₂, Ni(PPh₃)₂Br₂, 1,5-cyclooctadienebis(triphenyl)nickel, dichoro(2,2′-dipyridine)nickel, tetrakis(triphenylphosophine)nickel, NiO, NiF₂, NiCl₂, NiBr₂, NiI₂, NiAs, Ni(dmph)₂, BaNiS, or a combination thereof.

In yet another embodiment, the metal catalyst is a palladium(0) catalyst, wherein the palladium(0) catalyst is or is derived from Pd (PPh₃)₄, polymer-bound Pd (PPh₃)₄, Pd (PF₃)₄, Pd (PEtPh₂)₄, Pd (PEt₂Ph)₄, Pd[P(OR)₃]₄, Pd[P(4-MeC₆H₄)₃]₄, Pd (AsPh₃)₄, Pd (SbPh₃)₄, Pd (CO)₄, Pd (CN)₄, Pd (CNR)₄, Pd (R—C═C—R), Pd (PF₃)₂, Pd (dppe)₂, Pd (cod)₂, Pd (dppp)₂, or a combination thereof, wherein R is any aliphatic, aryl, or vinyl group.

Preferably, any of the methods described above provide a conducting polymer that has a regioregularity of at least about 87%, or preferably of at least about 92%, or more preferably of at least about 97%.

In one embodiment, the average weight molecular weight of the conducting polymer is about 5,000 to about 200,000, or preferably about 40,000 to about 60,000. In another embodiment, the conducting polymer prepared has a polydispersity index of about 1 to about 2.5, or preferably about 1.2 to about 2.2.

In one embodiment, the metal catalyst is added to the first monomer-manganese complex and the optional second manganese complex at about 0° C. to about 40° C. In another embodiment, the monomer-manganese complex and the optional second manganese complex is added to the metal catalyst at about 0° C. to about 40° C.

In one embodiment, a sub-stoichiometric amount of metal catalyst is employed, or preferably about 0.01 mol % to about 100 mol % of metal catalyst is employed, or more preferably about 0.1 mol % to about 5 mol % of metal catalyst is employed, or most preferably about 0.1 mol % to about 3 mol % of metal catalyst is employed.

In another embodiment, a sub-stoichiometric amount of nickel (II) catalyst is employed, or preferably about 0.01 mol % to about 100 mol % of nickel (II) catalyst is employed, or more preferably about 0.1 mol % to about 5 mol % of nickel (II) catalyst is employed, or most preferably about 0.1 mol % to about 3 mol % of nickel (II) catalyst is employed.

In yet another embodiment, a sub-stoichiometric amount of palladium(0) catalyst is employed, or preferably about 0.01 mol % to about 100 mol % of palladium(0) catalyst is employed, or more preferably about 0.1 mol % to about 5 mol % of palladium(0) catalyst is employed, or most preferably about 0.1 mol % to about 3 mol % of palladium(0) catalyst is employed.

The present invention also provides a method of preparing a conducting block copolymer including: a) combining a metal catalyst together with a first monomer-manganese complex to provide a conducting block copolymer intermediate, wherein the first monomer-manganese complex is prepared by combining a first dihalo-monomer together with an organometallic reagent to provide a first monomer-metal complex, which is combined together with a manganese (II) halide; b) combining a second monomer-manganese complex together with the conducting block copolymer intermediate to provide the conducting block copolymer, wherein the second monomer-manganese complex is prepared by combining a second dihalo-monomer together with an organometallic reagent to provide a second monomer-metal complex, which is combined together with a manganese (II) halide, wherein each dihalo-monomer is independently an aromatic or heteroaromatic group substituted by two halogens wherein the halogens are the same or different, wherein halogen is F, Cl, Br, or I, and wherein if the first dihalo-monomer has the same ring system as the second dihalo-monomer, then at least one of the monomer-metal complexes is substituted, and if both of the monomer-metal complexes are substituted, then the substituents are not the same.

In one embodiment, the conducting block copolymer is a regioregular block copolymer or regiorandom block copolymer. In another embodiment, the conducting block copolymer includes unsubstituted thiophene, 3-substituted-thiophene, 3,4-disubstituted-thiophene, or a combination thereof.

The present invention also provides a method of preparing a regioregular HT poly(thiophene) including combining a nickel (II) catalyst together with a thiophene-magnesium complex to provide a regioregular HT poly(thiophene), wherein the thiophene-magnesium complex is prepared by a method including contacting a 2,5-dihalo-thiophene metal complex with a magnesium halide.

Preferably, any of the methods described above provide a conducting block copolymer that has a regioregularity of at least about 87%, or preferably of at least about 92%, or more preferably of at least about 97%.

In one embodiment, the average weight molecular weight of the conducting block copolymer is about 5,000 to about 200,000, or preferably about 40,000 to about 60,000. In another embodiment, the conducting block copolymer prepared has a polydispersity index of about 1 to about 2.5, or preferably about 1.2 to about 2.2.

In one embodiment, the conducting block copolymer is a polythiophene block copolymer that is substituted in the 3 and/or 4 position with an (C₁-C₂₄)alkyl, a (C₁-C₂₄)alkylthio, a (C₁-C₂₄)alkylsilyl, or a (C₁-C₂₄)alkoxy group that may be optionally substituted with about one to about five ester, ketone, nitrile, amino, aryl, heteroaryl, or heterocyclyl groups, and one or more carbon atoms of the alkyl chain of the alkyl group may be optionally exchanged by about one to about ten O, S, or NH groups.

In another embodiment, the polythiophene block copolymer is substituted with a hexyl group and/or a pentyl group mono-substituted with an ethyl ester group.

In another embodiment, the regioregular HT poly(thiophene) is substituted in the 3 and/or 4 position with an (C₁-C₂₄)alkyl, a (C₁-C₂₄)alkylthio, a (C₁-C₂₄)alkylsilyl, or a (C₁-C₂₄)alkoxy group that may be optionally substituted with about one to about five ester, ketone, nitrile, amino, aryl, heteroaryl, or heterocyclyl groups, and one or more carbon atoms of the alkyl chain of the alkyl group may be optionally exchanged by about one to about ten O, S, or NH groups.

In yet another embodiment, the regioregular HT poly(thiophene) is substituted with a straight-chain, branched-chain, or cyclic (C₁-C₃₀)alkyl group, or preferably a straight-chain (C₁-C₁₂)alkyl group, or more preferably a hexyl group and/or a pentyl group mono-substituted with an ethyl ester group.

The present invention is also directed to an electronic device including a circuit constructed with a conducting polymer and/or the conducting block copolymer prepared by the methods described herein. In one embodiment, the device is a thin film transistor, a field effect transistor, a radio frequency identification tag, a flat panel display, a photovoltaic device, an electroluminescent display device, a sensor device, and electrophotographic device, or an organic light emitting diode.

The present invention provides a conducting polymer and/or the conducting block copolymer in the form of a thin film. In another embodiment, the conducting polymer film may include a dopant.

In one embodiment, the conducting polymer, a conducting block copolymer, or a regioregular HT poly(thiophene) prepared by any of the methods described herein, has a regioregularity of at least about 87%, preferably greater than about 92%, more preferably greater than about 95%.

Another embodiment is directed to a conducting polymer having at least about 92% regioregularity, an average weight molecular weight of about 30,000 to about 70,000, and a conductance of about 10⁻⁵ to about 10⁻⁶ seimens/centimeter (cm). Preferably the conducting polymer is a HT polythiophene is substituted with one or more organic or inorganic groups, or more preferably substituted with one or more alkyl, alkylthio, alkylsilyl, or alkoxy groups that are optionally substituted with about one to about five ester, ketone, nitrile, amino, aryl, heteroaryl, or heterocyclyl groups, and one or more carbon atoms of the alkyl chains of the alkyl groups are optionally exchanged by about one to about ten O, S, or NH groups.

Another embodiment is directed to a conducting block copolymer having at least about 92% regioregularity, an average weight molecular weight of about 30,000 to about 70,000, and a conductance of about 10⁻⁵ to about 10⁻⁶ seimens/centimeter (cm).

### DEFINITIONS

As used herein, certain terms have the following meanings. All other terms and phrases used in this specification have their ordinary meanings as one of skill in the art would understand. Such ordinary meanings may be obtained by reference to technical dictionaries, such as Hawley's Condensed Chemical Dictionary 11^{th} Edition, by Sax and Lewis, Van Nostrand Reinhold, New York, N.Y., 1987, and The Merck Index 11^{th} Edition, Merck & Co., Rahway N.J. 1989.

As used herein, the term “and/or” means any one of the items, any combination of the items, or all of the items with which this term is associated.

As used herein, the singular forms “a,” “an,” and “the” include plural reference unless the context clearly dictates otherwise. Thus, for example, a reference to “a formulation” includes a plurality of such formulations, so that a formulation of compound X includes formulations of compound X.

As used herein, the term “about” means a variation of 10 percent of the value specified, for example, about 50 percent carries a variation from 45 to 55 percent. For integer ranges, the term about can include one or two integers greater than and less than a recited integer.

As used herein, the term “alkyl” refers to a branched, unbranched, or cyclic hydrocarbon having, for example, from 1 to 30 carbon atoms, and often 1 to 12 carbon atoms. Examples include, but are not limited to, methyl, ethyl, 1-propyl (n-propyl), 2-propyl i-propyl), 1-butyl (n-butyl), 2-methyl-1-propyl (1-butyl), 2-butyl (sec-butyl), 2-methyl-2-propyl (t-butyl), 1-pentyl (n-pentyl), 2-pentyl, 3-pentyl, 2-methyl-2-butyl, 3-methyl-2-butyl, 3-methyl-1-butyl, 2-methyl-1-butyl, 1-hexyl, 2-hexyl, 3-hexyl, 2-methyl-2-pentyl, 3-methyl-2-pentyl, 4-methyl-2-pentyl, 3-methyl-3-pentyl, 2-methyl-3-pentyl, 2,3-dimethyl-2-butyl, 3,3-dimethyl-2-butyl, hexyl, octyl, decyl, dodecyl, and the like. The alkyl may be unsubstituted or substituted. The alkyl can also be optionally partially or fully unsaturated. As such, the recitation of an alkyl group includes both alkenyl and alkynyl groups. The alkyl may be a monovalent hydrocarbon radical, as described and exemplified above, or it may be a divalent hydrocarbon radical (i.e., alkylene).

As used herein, the term “alkylthio” refers to the group alkyl-S—, where alkyl is as defined herein. In one embodiment, alkylthio groups include, for example, methylthio, ethylthio, n-propylthio, iso-propylthio, n-butylthio, tert-butylthio, sec-butylthio, n-pentylthio, n-hexylthio, 1,2-dimethylbutylthio, and the like. The alkyl group of the alkylthio may be unsubstituted or substituted.

As used herein, the term “alkylsilyl” refers to the group alkyl-SiH₂— or alkyl-SiR₂—, where alkyl is as defined herein, and each R is independently H or alkyl. Thiophenes may be substituted by alkylsilyl groups by any of the many techniques known to those of skill in the art, typically by coupling the thiophene with an alkylsilyl halide, many of which are disclosed in the Aldrich Handbook of Fine Chemicals, 2007-2008, Milwaukee, Wis.

As used herein, the term “alkynyl” refers to a monoradical branched or unbranched hydrocarbon chain, having a point of complete unsaturation (i.e., a carbon-carbon, sp triple bond). In one embodiment, the alkynyl group can have from 2 to 10 carbon atoms, or 2 to 6 carbon atoms. In another embodiment, the alkynyl group can have from 2 to 4 carbon atoms. This term is exemplified by groups such as ethynyl, 1-propynyl, 2-propynyl, 1-butynyl, 2-butynyl, 3-butynyl, 1-hexynyl, 2-hexynyl, 3-hexynyl, 1-octynyl, and the like. The alkynyl can be unsubstituted or substituted.

As used herein, the term “alkoxy” refers to the group alkyl-O—, where alkyl is as defined herein. In one embodiment, alkoxy groups include, for example, methoxy, ethoxy, n-propoxy, iso-propoxy, n-butoxy, tert-butoxy, sec-butoxy, n-pentoxy, n-hexoxy, 1,2-dimethylbutoxy, and the like. The alkyl group of the alkoxy may be unsubstituted or substituted.

As used herein, the term “aryl” refers to an aromatic hydrocarbon group derived from the removal of one hydrogen atom from a single carbon atom of a parent aromatic ring system. The radical may be at a saturated or unsaturated carbon atom of the parent ring system. The aryl group can have from 6 to 18 carbon atoms. The aryl group can have a single ring (e.g., phenyl) or multiple condensed (fused) rings, wherein at least one ring is aromatic (e.g., naphthyl, dihydrophenanthrenyl, fluorenyl, or anthryl). Typical aryl groups include, but are not limited to, radicals derived from benzene, naphthalene, anthracene, biphenyl, and the like. The aryl may be unsubstituted or optionally substituted, as described above for alkyl groups.

As used herein, the term “block copolymer” refers to any polymer prepared by coupling functional polyvalent polymers such as an AB block copolymer. The block copolymers of some embodiments may be an AB block copolymer, wherein the A block is a polythiophene, and the B block is also polythiophene. The block copolymers of some embodiments may also be an ABA block copolymer or an ABC block copolymer, wherein the A block is a polythiophene, wherein the B block is also a polythiophene, and wherein the C block is also a polythiophene. Further, the block copolymers of some embodiments may be an AB block copolymer, wherein the A block is a polythiophene, and the B block is another conductive polymer, for example, poly(pyrrole). The block copolymers of some embodiments may also be an ABA block copolymer or an ABC block copolymer, wherein the A block is a polythiophene, wherein the B block is another conductive polymer, for example, poly(pyrrole), and wherein the C block is another conductive polymer, for example, poly(analine).

As used herein, the term “conducting polymer” refers to polymer that conducts electricity. Typically, conducting polymers are polymers, which contain in the main chain principally sp²-hybridised carbon atoms, which may also be replaced by corresponding heteroatoms. In the simplest case, this means the alternating presence of double and single bonds in the main chain. Principally means that naturally occurring defects, which result in conjugation interruptions do not devalue the term “conducting polymer.” Furthermore, the term conducting is likewise used in this application text if, for example, arylamine units and/or certain heterocycles (i.e., conjugation via N, O or S atoms) and/or organometallic complexes (i.e., conjugation via the metal atom) are present in the main chain. By contrast, units such as, for example, simple alkyl bridges, (thio)ether, ester, amide, or imide links are defined as non-conducting segments. A partially conducting polymer is intended to mean a polymer in which relatively long conducting sections in the main chain are interrupted by non-conducting sections, or which contains relatively long conducting sections in the side chains of a polymer, which is non-conducting in the main chain.

As used herein, the terms “film” or “thin film” refers to a self-supporting or free-standing film that shows mechanical stability and flexibility, as well as a coating or layer on a supporting substrate or between two substrates.

As used herein, the term “Grignard-ate complex” refers to the complexing or three-dimensional association of one or more Grignard reagents with an alkali salt to form to form the three-dimensional ate complex.

As used herein, the terms “halo” and “halogen” refer to a fluoro, chloro, bromo, or iodo group, substituent, or radical.

As used herein, the term “heteroaryl” is defined herein as a monocyclic, bicyclic, or tricyclic ring system containing one, two, or three aromatic rings and containing at least one nitrogen, oxygen, or sulfur atom in an aromatic ring, and which may be unsubstituted or substituted, for example, with one or more, and in particular one to three, substituents, as described above in the definition of “substituted.” Examples of heteroaryl groups include, but are not limited to, 2H-pyrrolyl, 3H-indolyl, carboliny, [symbol] 4H-quinolizinyl, acridinyl, benzo[b]thienyl, benzothiazolyl, carbazolyl, chromenyl, cinnolinyl, dibenzo[b,d]furanyl, furazanyl, furyl, imidazolyl, imidizolyl, indazolyl, indolisinyl, indolyl, isobenzofuranyl, isoindolyl, isoquinolyl, isothiazolyl, isoxazolyl, naphthyridinyl, oxazolyl, perimidinyl, phenanthridinyl, phenanthrolinyl, phenarsazinyl, phenazinyl, phenothiazinyl, phenoxathiinyl, phenoxazinyl, phthalazinyl, pteridinyl, purinyl, pyranyl, pyrazinyl, pyrazolyl, pyridazinyl, pyridyl, pyrimidinyl, pyrimidinyl, pyrrolyl, quinazolinyl, quinolyl, quinoxalinyl, thiadiazolyl, thianthrenyl, thiazolyl, thienyl, triazolyl, tetrazolyl, and xanthenyl. In one embodiment the term “heteroaryl” denotes a monocyclic aromatic ring containing five or six ring atoms containing carbon and 1, 2, 3, or 4 heteroatoms independently selected from non-peroxide oxygen, sulfur, and N(Z) wherein Z is absent or is H, O, alkyl, aryl, or (C₁-C₆)alkylaryl. In another embodiment heteroaryl denotes an ortho-fused bicyclic heterocycle of about eight to ten ring atoms derived therefrom, particularly a benz-derivative or one derived by fusing a propylene, trimethylene, or tetramethylene diradical thereto.

As used herein, the terms “heterocycle” or “heterocyclyl” refer to a saturated or partially unsaturated ring system, containing at least one heteroatom selected from the group oxygen, nitrogen, and sulfur, and optionally substituted with one or more groups as defined herein under the term “substituted.” A heterocycle may be a monocyclic, bicyclic, or tricyclic group containing one or more heteroatoms. A heterocycle group also can contain an oxo group (═O) attached to the ring. Non-limiting examples of heterocycle groups include 1,3-dihydrobenzofuran, 1,3-dioxolane, 1,4-dioxane, 1,4-dithiane, 2H-pyran, 2-pyrazoline, 4H-pyran, chromanyl, imidazolidinyl, imidazolinyl, indolinyl, isochromanyl, isoindolinyl, morpholine, piperazinyl, piperidine, piperidyl, pyrazolidine, pyrazolidinyl, pyrazolinyl, pyrrolidine, pyrroline, quinuclidine, and thiomorpholine. The term “heterocycle” also includes, by way of example and not limitation, a monoradical of the heterocycles described in Paquette, Leo A., Principles of Modern Heterocyclic Chemistry (W. A. Benjamin, New York, 1968), particularly Chapters 1, 3, 4, 6, 7, and 9, The Chemistry of Heterocyclic Compounds, A Series of Monographs” (John Wiley & Sons, New York, 1950 to present), in particular Volumes 13, 14, 16, 19, and 28, and J. Am. Chem. Soc. 1960, 82, 5566. In one embodiment, the term “heterocycle” includes a “carbocycle” as defined herein, wherein one or more (e.g., 1, 2, 3, or 4) carbon atoms have been replaced with a heteroatom (e.g., O, N, or S).

As used herein, the term “high regioregularity” refers to a compound or polymer that is at least about 85% regioregular, preferably at least about 87% regioregular, more preferably at least about 90% regioregular, even more preferably at least about 92% regioregular, yet more preferably at least about 95% regioregular, further preferably at least about 97% regioregular, or most preferably at least about 99% regioregular.

As used herein, the terms “HT polythiophene” or “HT” refers to the head-to-tail orientation of monomers in a polythiophene. The polythiophene may be an unsubstituted polythiophene, a poly(3-substituted-thiophene), or a poly(3,4-disubstituted-thiophene). The percent regioregularity present in a polythiophene may be determined by standard ¹H NMR techniques. The percent regioregularity may be increased by various techniques, including Soxhlet extraction, precipitation, and recrystallization.

As used herein, the term “metal catalyst” refers to a polymerization catalyst for the monomer-metal complex.

As used herein, the term “monomer-manganese complex” refers to a thiophene moiety that is associated with a manganese atom. The thiophene-manganese complex is typically a thiophene-manganese halide complex. The halide, or “halo” group can be fluoro, chloro, bromo, or iodo.

As used herein, the term “monomer-metal complex” refers to a monomer moiety that is associated with a metal atom.

As used herein, the terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the invention.

As used herein, the term “regioregular” refers to a polymer where the monomers are arranged in a substantially head-to-tail orientation. For example, although many conventional polymers have all α-α couplings, they have a mixture of head-head, head-tail, and tail-tail orientations.

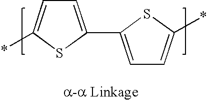

Thus, conventional polymers are not completely regioregular (formerly referred to as regiospecific and stereospecific), i.e., with all head-head, head-tail, or tail-tail orientations. Nor are conventional polymers completely regiorandom, i.e., with an equal amount of each orientation (25% head-tail & head-tail, 25% head-tail & head-head, 25% tail-tail & head-tail, 25% tail-tail & head-head).

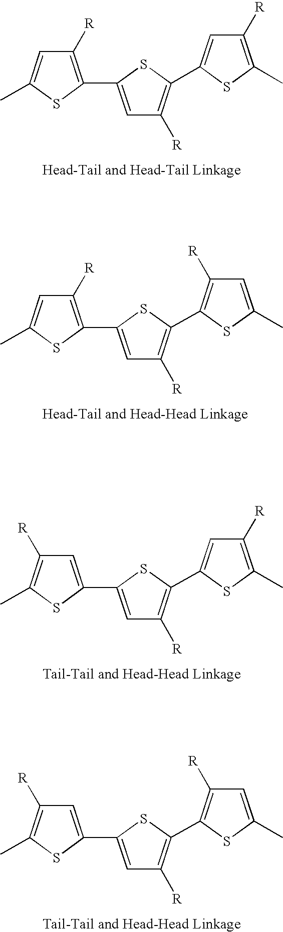

For further description and discussion of the terms regiorandom and regioregular (or regioselective), see U.S. Pat. No. 5,756,653, which is hereby incorporated by reference.

As used herein, the term “room temperature” refers to about 23° C.

As used herein, the term “Rieke zinc (Zn*)” refers to an activated form of zinc prepared by the method described in U.S. Pat. No. 5,756,653, which is hereby incorporated by reference.

As used herein, the term “substituted” is intended to indicate that one or more (e.g., 1, 2, 3, 4, or 5, in some embodiments 1, 2, or 3, and in other embodiments 1 or 2) hydrogen atoms on the group indicated in the expression using “substituted” is replaced with a selection from the indicated organic or inorganic group(s), or with a suitable organic or inorganic group known to those of skill in the art, provided that the indicated atom's normal valency is not exceeded, and that the substitution results in a stable compound. Suitable indicated organic or inorganic groups include, for example, alkyl, alkenyl, alkynyl, alkoxy, halo, haloalkyl, hydroxy, hydroxyalkyl, aryl, heteroaryl, heterocyclyl, cycloalkyl, alkanoyl, alkoxycarbonyl, amino, alkylamino, dialkylamino, trifluoromethylthio, difluoromethyl, acylamino, nitro, trifluoromethyl, trifluoromethoxy, carboxy, carboxyalkyl, keto, thioxo, alkylthio, alkylsulfinyl, alkylsulfonyl, alkylsilyl, and cyano. Additionally, the suitable indicated groups can include, for example, —X, —R, —O⁻, —OR, —SR, —S⁻, —NR₂, —NR₃, ═NR, —CX₃, —CN, —OCN, —SCN, —N═C═O, —NCS, —NO, —NO₂, ═N₂, —N₃, NC(═O)R, —C(═O)R, —C(═O)NRR —S(═O)₂O⁻, —S(═O)₂OH, —S(═O)₂R, —OS(═O)₂OR, —S(═O)₂NR, —S(═O)R, —OP(═O)O₂RR, —P(═O)O₂RR, —P(═O)(O⁻)₂, —P(═O)(OH)₂, —C(═O)R, —C(═O)X, —C(S)R, —C(O)OR, —C(O)O⁻, —C(S)OR, —C(O)SR, —C(S)SR, —C(O)NRR, —C(S)NRR, —C(NR)NRR, where each X is independently a halogen (or “halo” group): F, Cl, Br, or I, and each R is independently H, alkyl, aryl, heterocyclyl, protecting group or prodrug moiety. As would be readily understood by one skilled in the art, when a substituent is keto (i.e., ═O), or thioxo (i.e., ═S), or the like, two hydrogen atoms on the substituted atom are replaced.

As used herein, the terms “stable compound” and “stable structure” are meant to indicate a compound or polymer that is sufficiently robust to survive isolation to a useful degree of purity from a reaction mixture. The compounds and polymers are typically stable compounds. Intermediates and metal complexes may be somewhat instable or non-isolable components of these methods.

As used herein, the term “thiophene-metal complex” refers to a thiophene moiety that is associated with a metal atom. The thiophene-metal complex is typically a thiophene-zinc halide complex. The “halide” or “halo” group may be fluoro, chloro, bromo, or iodo.

As to any of the above groups, which contain one or more substituents, it is understood, of course, that such groups do not contain any substitution or substitution patterns that are sterically impractical and/or synthetically non-feasible. In addition, the compounds of this invention include all stereochemical isomers arising from the substitution of these compounds.

### DETAILED DESCRIPTION OF THE INVENTION

The present invention provides methods of preparing conducting polymers and the resulting polymers prepared thereby. In these methods, dihalo-monomers are combined together with organometallic reagents to provide monomer-metal complexes. Next, the monomer-metal complexes are combined together with a manganese (II) halide to provide monomer-manganese complexes. Finally, the monomer-manganese complexes are combined together with metal catalysts to afford conducting polymers.

One advantage of these methods is that transmetallation of the monomer-metal complex with manganese allows for polymerization at a lower temperature than many known methods, such as those described in U.S. Pat. No. 6,166,172. While not intending to be bound by theory, it is believed that transmetallation to provide the monomer-manganese complex reduces the activation energy or energetic barrier for polymerizing the monomer. The use of a monomer-manganese complex is believed to provide a more energetic polymerization that does not require additional heating, and the resulting polymer has a higher regioregularity than does a polymer produced by heretofore known methods.

Another advantage is that the methods described herein produce polymers of greater regioregularity (higher percentage of head-to tail monomer linkages) with lower catalyst loadings.

The conducting polymers may be, for example, regioregular and regiorandom conducting polymers and block copolymers. Regioregular conducting polymers and block copolymers can be provided, for example, through use of a nickel (II) catalyst to accomplish the polymerization. Alternatively, regiorandom conducting polymers and block copolymers can be provided, for example, through use of a palladium (0) catalyst to accomplish the polymerization.

The conducting polymers may be, for example, unsubstituted or substituted homopolymers, unsubstituted or substituted random copolymers, or unsubstituted or substituted block copolymers depending upon the reactants and the reaction sequence. For example, aromatic homopolymers, random copolymers, and block copolymers may be prepared from one or more aromatic monomers, respectively. Heteroaromatic homopolymers, random copolymers, and block copolymers may be prepared, for example, from heteroaromatic monomers. Further, combinations of aromatic and heteroaromatic monomers may also be used, for example, to prepare random copolymers and block copolymers.

Preferably, the conducting polymers are, for example, unsubstituted or substituted polythiophene homopolymers, poly(3-substituted-thiophene) homopolymers, poly(3-substituted-thiophene) copolymers, poly(3,4-disubstituted-thiophene) homopolymers, poly(3,4-disubstituted-thiophene) copolymers, copolymers including unsubstituted thiophene, 3-substituted-thiophene, 3,4-disubstituted-thiophene, or a combination thereof, polythiophene block copolymers including unsubstituted thiophene, 3-substituted-thiophene, 3,4-disubstituted-thiophene, or a combination thereof, or block copolymers including a block of polythiophene and a block of another aromatic or heteroaromatic conducting polymer.

### General Preparatory Methods

A number of exemplary methods for the preparation of polymers of the invention are provided herein. These methods are intended to illustrate the nature of such preparations and are not intended to limit the scope of applicable methods. Certain compounds can be used as intermediates for the preparation of other compounds or polymers of the invention.

Scheme 1 illustrates one embodiment directed to method of preparing a conducting homopolymer in which one kind of aromatic monomer or heteroaromatic monomer is used.

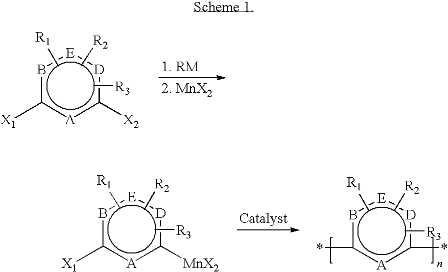

wherein

A, B, and D are each independently sulfur, nitrogen, oxygen, phosphorous, silicon, or carbon;

E may be absent, sulfur, nitrogen, oxygen, phosphorus, silicon, or carbon, and when absent, B forms a bond with D;

X₁ and X₂ are each independently halogen;

n indicate the number of monomeric units present to provide the desired molecular weight of the polymer;

R₁, R₂, and R₃ are each independently absent, alkyl, alkylthio, alkylsilyl, or alkoxy that is optionally substituted with about one to about five ester, ketone, nitrile, amino, halo, aryl, heteroaryl, or heterocyclyl groups, and one or more carbon atoms of the alkyl chain of the alkyl group may be optionally exchanged by about one to about ten O, S, and/or NP groups wherein P is a substituent as described above or a nitrogen protecting group, RM is an organometallic reagent, and MnX₂ is a manganese halide, wherein X is F, Cl, Br, or I, wherein the circle indicates an aromatic structure in which the A, B, D, and E groups have additional hydrogen atoms needed to maintain a neutral ring structure.

In this embodiment, a dihalo-monomer is combined together with an organometallic reagent (RM) to provide a monomer-metal complex. Next, the monomer-metal complex is combined together with a manganese (II) halide to provide a monomer-manganese complex, which is combined together with a metal catalyst to provide the conductive polymer.

Scheme 2 illustrates one embodiment directed to method of preparing a conducting random copolymer in which two kinds of aromatic monomers, heteroaromatic monomers, or a combination thereof, are used.

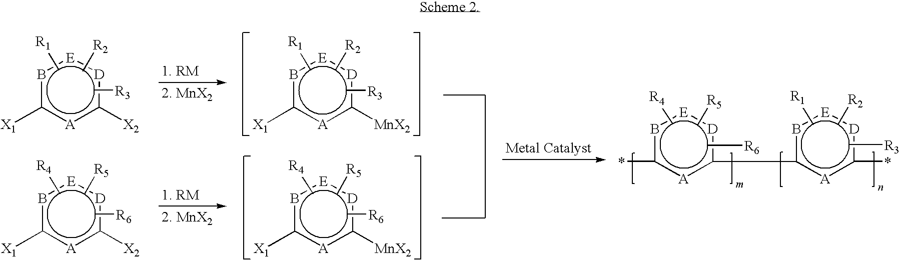

wherein

A, B, and D are each independently sulfur, nitrogen, oxygen, phosphorous, silicon, or carbon;

E may be absent, sulfur, nitrogen, oxygen, phosphorus, silicon, or carbon, and when absent, B forms a bond with D;

X₁ and X₂ are each independently halogen;

m and n indicate the number of monomeric units present to provide the desired molecular weight of the copolymer;

R₁, R₂, R₃, R₄, R₅, and R₆ are each independently absent, alkyl, alkylthio, alkylsilyl, or alkoxy that is optionally substituted with about one to about five ester, ketone, nitrile, amino, halo, aryl, heteroaryl, or heterocyclyl groups, and one or more carbon atoms of the alkyl chain of the alkyl group may be optionally exchanged by about one to about ten O, S, and/or NP groups wherein P is a substituent as described above or a nitrogen protecting group, RM is an organometallic reagent, and MnX₂ is a manganese halide, wherein X is F, Cl, Br, or I, wherein the circle indicates an aromatic structure in which the A, B, D, and E groups have additional hydrogen atoms needed to maintain a neutral ring structure.

In this embodiment, each dihalo-monomer is combined together with an organometallic reagent (RM) to provide the monomer-metal complexes. Next, each monomer-metal complex is combined together with a manganese (II) halide to provide the monomer-manganese complexes, which are combined together with a metal catalyst to provide the conductive polymer.

Scheme 3 illustrates one embodiment directed to method of preparing a conducting block copolymer in which two kinds of aromatic monomers, heteroaromatic monomers, or a combination thereof, are used.

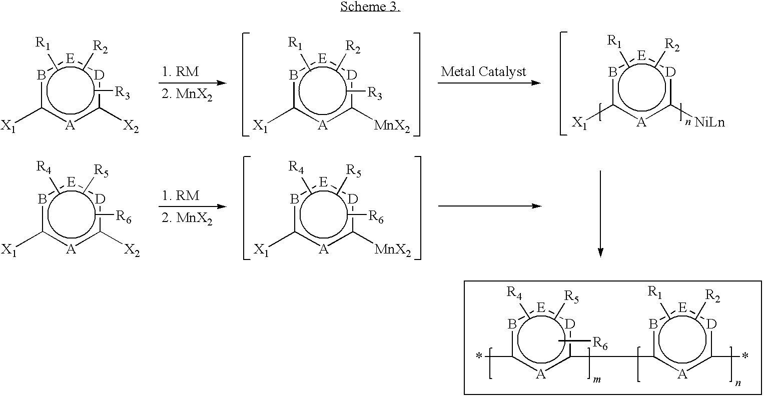

wherein

A, B, and D are each independently sulfur, nitrogen, oxygen, phosphorous, silicon, or carbon;

E may be absent, sulfur, nitrogen, oxygen, phosphorus, silicon, or carbon, and when absent, B forms a bond with D;

X₁ and X₂ are each independently halogen;

m and n indicate the number of monomeric units present to provide the desired molecular weight of the block copolymer;

R₁, R₂, R₃, R₄, R₅, and R₆ are each independently absent, alkyl, alkylthio, alkylsilyl, or alkoxy that is optionally substituted with about one to about five ester, ketone, nitrile, amino, halo, aryl, heteroaryl, or heterocyclyl groups, and one or more carbon atoms of the alkyl chain of the alkyl group may be optionally exchanged by about one to about ten O, S, and/or NP groups wherein P is a substituent as described above or a nitrogen protecting group, RM is an organometallic reagent, and MnX₂ is a manganese halide, wherein X is F, Cl, Br, or I, wherein the circle indicates an aromatic structure in which the A, B, D, and E groups have additional hydrogen atoms needed to maintain a neutral ring structure. In some embodiments, more than two kinds of monomers may be used.

In this embodiment, each dihalo-monomer is combined together with an organometallic reagent (RM) to form the monomer metal complexes. Next, each monomer-metal complex is combined together with a manganese (II) halide to provide the monomer-manganese complexes. A metal catalyst is combined together with a first monomer-manganese complex to provide a conducting polymer intermediate. Then, the second monomer-manganese complex is combined together with (i.e., added to) conducting polymer intermediate to provide the conducting block copolymer.

In another embodiment, the present invention provides a method of preparing a conducting block copolymer including: a) combining a metal catalyst together with a first monomer-manganese complex to provide a conducting block copolymer intermediate under conditions which provide for living polymerization; b) combining a second monomer-manganese complex together with the conducting block copolymer intermediate to provide the conducting AB block copolymer, wherein at least one of the monomer-manganese complexes is substituted, and if both of the monomer-metal complexes are substituted, then the substituents are not the same.

In another embodiment, the method further includes chain extending the conducting AB block copolymer with a third monomer-manganese complex which optionally is the same as the first monomer-manganese complex. In yet another embodiment, the method further includes chain extending the conducting AB block copolymer to form a conducting ABA block copolymer.

In one embodiment, the method further includes steps of chain extension to form conducting ABC block copolymer. In a preferred embodiment, the conducting AB block copolymer is a polythiophene block copolymer.

A variety of organometallic reagents can be used to form the monomer-metal complex. Suitable organometallic reagents include Grignard reagents, Grignard-ate complexes, alkyl lithium reagents, alkyl lithium cuprates, alkyl aluminum reagents, and organozinc reagents, wherein the organozinc reagent is RZnX, R₂ZnX, or R₃ZnM, wherein R is (C₂-C₁₂) alkyl, M is magnesium, manganese, lithium, sodium, or potassium, and X is F, Cl, Br, or I. (see, e.g., PCT Patent Application Publication No. WO 2007/011945, which is incorporated herein by reference). Commercial reagents, such as Grignard, Grignard-ate complexes, alkyl lithium, alkyl lithium cuprate, alkyl aluminum, and organozinc reagents, wherein the organozinc reagent is RZnX, R₂ZnX, or R₃ZnM, wherein R is (C₂-C₁₂) alkyl, M is magnesium, manganese, lithium, sodium, or potassium, and X is F, Cl, Br, or I, can be employed, such as those disclosed in the Aldrich Handbook of Fine Chemicals, 2007-2008, Milwaukee, Wis. Any suitable amount of the organometallic reagent can be used. Typically, one to about five equivalents of the organometallic reagent can be employed, based on the amount of the monomer starting material. The entire reaction sequence can be carried out without any isolation of intermediates.

In one embodiment, a regioregular block copolymer will be formed if the metal catalyst is a nickel (II) catalyst. In another embodiment, a regiorandom block copolymer will be formed if a palladium (0) catalyst is used.

The preferred conditions for the formation of the monomer-metal complex may include, for example, the use of an inert atmosphere (e.g., nitrogen, helium, or argon), and suitable temperatures and times.

Typically, the temperature of the formation of the monomer-metal complex is at least about −78° C., preferably at least about 0° C., and more preferably at least about 23° C. Typically, the temperature of the formation of the monomer-metal complex is no greater than about 100° C., preferably no greater than about 60° C., and more preferably no greater than about 40° C.

Typically, the formation of the monomer-metal is sufficiently complete within at least about 5 minutes, and preferably at least about 30 minutes. Typically, the reaction time is no more than about 24 hours, more preferably no more than about 8 hours, and even more preferably no more than about 1 hour.

The preferred conditions for the formation of the monomer-manganese complex may include, for example, the use of an inert atmosphere (e.g., nitrogen, helium, or argon), and suitable temperatures and times.

Typically, the temperature of the formation of the monomer-metal complex is at least about −78° C., preferably at least about 0° C., and more preferably at least about 23° C. Typically, the temperature of the formation of the monomer-manganese complex is no greater than about 100° C., preferably no greater than about 60° C., and more preferably no greater than about 40° C.

Typically, the formation of the monomer-manganese is sufficiently complete within at least about 5 minutes, and preferably at least about 30 minutes. Typically, the reaction time is no more than about 24 hours, more preferably no more than about 8 hours, and even more preferably no more than about 1 hour.

The preferred conditions for the polymerization of the monomer-metal to form a conducting polymer may include, for example, the use of an inert atmosphere (e.g., nitrogen, helium, or argon), and suitable temperatures and times.

Typically, the monomer-metal complex is added to the metal catalyst to provide the conducting polymer or the conducting polymer intermediate. The metal catalyst may also be added to monomer-metal complex to provide the conducting polymer or the conducting polymer intermediate.

Typically, the temperature of the polymerization is at least −78° C., preferably at least 0° C., and more preferably at least 23° C. Typically, the temperature of the polymerization is no greater than the boiling point of the solvent used, preferably no greater than 60° C., and more preferably no greater than 40° C.

Typically, the polymerization is sufficiently complete within at least 2 hours, and preferably at least 24 hours. Typically, the polymerization is no more than 72 hours, more preferably no more than 48 hours, and even more preferably no more than 30 hours.

The polymerization can be carried out in the same solvent as was the preparation of the monomer-metal complex.

Suitable dihalo-monomers include, for example, any dihalo-substituted or unsubstituted (C₆-C₃₀)aryl monomer or dihalo-substituted or unsubstituted (C₃-C₃₀)heteroaryl monomer. The aromatic or heteroaromatic monomer may be, for example, benzene, thiophene, pyrrole, furan, aniline, phenylene vinylene, thienylene vinylene, bis-thienylene vinylene, acetylene, fluorene, arylene, isothianaphthalene, p-phenylene sulfide, thieno[2,3-b]thiophene, thieno[2,3-c]thiophene, thieno[2,3-d]thiophene, naphthalene, benzo[2,3]thiophene, benzo[3,4]thiophene, biphenyl, or bithiophenyl, and the like. The aromatic or heteroaromatic monomer has from zero to about three substituents other than halogen. The substituents are each independently (C₁-C₂₄)alkyl, (C₁-C₂₄)alkylthio, (C₁-C₂₄)alkylsilyl, or (C₁-C₂₄)alkoxy that may be optionally substituted with about one to about five ester, ketone, nitrile, amino, aryl, heteroaryl, or heterocyclyl groups, and one or more carbon atoms of the alkyl chain of the alkyl group may be optionally exchanged by about one to about ten O, S, or NH groups.

Suitable dihalo-monomers include, for example, a 2,5-dihalo-thiophene, a 2,5-dihalo-pyrrole, a 2,5-dihalo-furan, a 1,3-dihalobenzene, a 2,5-dihalo-3-substituted-thiophene, a 2,5-dihalo-3-substituted-pyrrole, a 2,5-dihalo-3-substituted-furan, a 1,3-dihalo-2-substituted-benzene, a 1,3-dihalo-4-substituted-benzene, a 1,3-dihalo-5-substituted-benzene, a 1,3-dihalo-6-substituted-benzene, a 1,3-dihalo-2,4-disubstituted-benzene, a 1,3-dihalo-2,5-disubstituted-benzene, a 1,3-dihalo-2,6-disubstituted-benzene, a 1,3-dihalo-4,5-disubstituted-benzene, a 1,3-dihalo-4,6-disubstituted-benzene, a 1,3-dihalo-2,4,5-trisubstituted-benzene, a 1,3-dihalo-2,4,6-trisubstituted-benzene, a 1,3-dihalo-2,5,6-trisubstituted-benzene, a 1,4-dihalo-2-substituted-benzene, a 1,4-dihalo-3-substituted-benzene, a 1,4-dihalo-5-substituted-benzene, a 1,4-dihalo-6-substituted-benzene, a 1,4-dihalo-2,3-disubstituted-benzene, a 1,4-dihalo-2,5-disubstituted-benzene, a 1,4-dihalo-2,6-disubstituted-benzene, a 1,4-dihalo-3,5-disubstituted-benzene, a 1,4-dihalo-3,6-disubstituted-benzene, a 1,4-dihalo-3,5,6-trisubstituted-benzene, a 2,5-dihalo-3,4-disubstituted-thiophene, a 2,5-dihalo-3,4-disubstituted-pyrrole, a 2,5-dihalo-3,4-disubstituted-furan, or a combination thereof.

A preferred embodiment is provided below in Scheme 4.

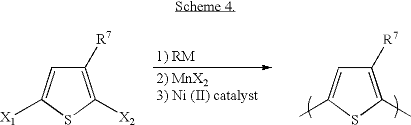

wherein X₁ and X₂ are each independently halogen, R⁷ is an alkyl, alkylthio, alkylsilyl, or alkoxy group that is optionally substituted with one to about five ester, ketone, nitrile, amino, halo, aryl, heteroaryl, or heterocyclyl groups, and the alkyl chain of the alkyl group is optionally interrupted by one to about ten O, S, and/or NP groups wherein P is a substituent as described above or a nitrogen protecting group; RM is an organometallic reagent that can react with the thiophene to form a thiophene metal complex that undergoes transmetallation when introduced to a manganese(II) salt, such as MnF₂, MnCl₂, MnBr₂, or MnI₂; n indicate the number of monomeric units present to provide the desired molecular weight of the polymer; and the Ni(II) catalyst is any nickel(II) catalyst that effectuates polymerization of the thiophene manganese complex.

In one embodiment, the transmetallation of a thiophene-metal complex with manganese salts provides a thiophene-manganese complex that undergoes facile polymerization with a Ni(II) catalyst. The thiophene-metal complex is typically substituted by a metal at the 2- or 5-position, for example, by the exchange of the metal for a halogen that was positioned at the 2- or 5-position. The thiophene-metal complex can be converted to a thiophene-manganese complex by transmetallation. Thereafter, the thiophene-manganese complex can be readily polymerized by a Ni(II) catalyst to provide a highly regioregular 3-substituted polythiophene.

In particular, for example, a 2,5-dihalo-3-substituted-thiophene can be dissolved in a suitable solvent, such as an ethereal solvent, for example, tetrahydrofuran. The reaction flask can be cooled before introduction of the organometallic reagent. The organometallic reagent can be added into the reaction flask and stirred for a sufficient period of time to form the thiophene-metal complex by exchanging a group on the organometallic complex with one of the X (halo) groups of the thiophene. After the thiophene-metal complex has formed, a manganese halide can be added to the reaction mixture, optionally allowing the reaction to warm to ambient temperature, to afford a transmetallated species.

After transmetallation, the reaction can be allowed to settle and the solution of the reaction vessel can be transferred to a flask containing a nickel(II) catalyst, optionally dissolved in an ethereal solvent. Alternatively after transmetallation, the flask containing the nickel(II) catalyst may be added to the reaction vessel containing the transmetallated species. The resulting mixture can be stirred for a sufficient amount of time to effect the formation of the polythiophene, which typically precipitates from the reaction mixture. The polythiophene can be isolated by transferring the reaction mixture into a volume of solvent in which the polythiophene is substantially insoluble. Further work-up can include filtering, washing with methanol, and drying under high vacuum. Additional purification can be carried out by Soxhlet extraction with, for example, a hydrocarbon solvent, such as hexanes.

The formation of the polythiophene can be carried out at any suitable and effective temperature. In one embodiment, the polymerization is carried out at temperatures of about −100° C. to about 150° C. In another embodiment, the polymerization is conducted at temperatures of about −20° C. to about 100° C. The polymerization can be carried out in the same solvent as was the preparation of the thiophene metal complex. The polymerization reaction step with the Ni(II) catalyst can be carried out at about 0° C. to about the boiling point of the solvent used in this step of the reaction. Typically, the thiophene-manganese complex is contacted with the nickel(II) catalyst at about −80° C. to about 35° C., or preferably at about −10° C. to about 30° C., or more preferably at about 0° C. to about 27° C.

As discussed above, transmetallation of the monomer-metal complex with manganese allows for polymerization at a lower temperature than many known methods, such as those described in U.S. Pat. No. 6,166,172. In a preferred embodiment, polymerization of the thiophene-manganese complex proceeds smoothly at ambient temperatures (e.g., about 18° C. to about 25° C.) without the need for a heat source or for refluxing conditions.

### 2,5-Dihalo-Thiophenes

In a preferred embodiment, the dihalo-monomers are dihalo-thiophenes. The 2,5-dihalo-thiophene may be a 2,5-dihalo-3-substituted-thiophene, an unsubstituted 2,5-dihalo-thiophene, or a 2,5-dihalo-3,4-disubstituted-thiophene. The dihalothiophenes are typically difluoro-, dichloro-, dibromo-, or diiodo-thiophenes, which may be unsubstituted or substituted in the 3 and/or 4 positions. Combinations of 2,5-dihalothiophenes, 2,5-dihalo-3-substituted-thiophenes, and 2,5-dihalo-3,4-disubstituted-thiophenes may also be employed.

Suitable unsubstituted dihalothiophenes may include, for example, 2,5-difluorothiophene, 2,5-dichlorothiophene, 2,5-dibromothiophene, 2,5-diiodothiophene, 2-fluoro-5-chlorothiophene, 2-fluoro-5-bromothiophene, 2-fluoro-5-iodothiophene, 2-chloro-5-fluorothiophene, 2-chloro-5-bromothiophene, 2-chloro-5-iodothiophene, 2-bromo-5-fluorothiophene, 2-bromo-5-chlorothiophene, 2-bromo-5-iodothiophene, 2-iodo-5-fluorothiophene, 2-iodo-5-chlorothiophene, and 2-iodo-5-bromothiophene. These 2,5-dihalothiophenes, which are not substituted in the 3- and/or 4-positions, may be useful to prepare a block copolymer that includes, for example, an unsubstituted polythiophene block and one or more substituted polythiophene blocks. For example, an unsubstituted polythiophene may be combined with a block of either 3-substituted polythiophene and/or a block of 3,4-disubstituted polythiophene. Alternatively, a 3-substituted polythiophene can be combined with a block of 3,4-disubstituted polythiophene.

The dihalothiophenes listed above may be substituted in the 3 and/or 4-positions with an (C₁-C₂₄)alkyl, a (C₁-C₂₄)alkylthio, a (C₁-C₂₄)alkylsilyl, or a (C₁-C₂₄)alkoxy group that may be optionally substituted with about one to about five ester, ketone, nitrile, amino, aryl, heteroaryl, or heterocyclyl groups, and one or more carbon atoms of the alkyl chain of the alkyl group may be optionally exchanged by about one to about ten O, S, or NH groups.

Suitable 2,5-dihalo-3-substituted-thiophenes may include, for example, 2,5-difluoro-3-hexylthiophene, 2,5-dichloro-3-hexylthiophene, 2,5-dibromo-3-hexylthiophene, 2,5-diiodo-3-hexylthiophene, 2-fluoro-3-hexyl-5-chlorothiophene, 2-fluoro-3-hexyl-5-bromothiophene, 2-fluoro-3-hexyl-5-iodothiophene, 2-chloro-3-hexyl-5-fluorothiophene, 2-chloro-3-hexyl-5-bromothiophene, 2-chloro-3-hexyl-5-iodothiophene, 2-bromo-3-hexyl-5-fluorothiophene, 2-bromo-3-hexyl-5-chlorothiophene, 2-bromo-3-hexyl-5-iodothiophene, 2-iodo-3-hexyl-5-fluorothiophene, 2-iodo-3-hexyl-5-chlorothiophene, 2-iodo-3-hexyl-5-bromothiophene, ethyl-5-(2-5-difluorothiophen-3-yl)pentanoate, ethyl-5-(2-5-dichlorothiophen-3-yl)pentanoate, ethyl-5-(2-5-dibromothiophen-3-yl)pentanoate, ethyl-5-(2-5-diiodothiophen-3-yl)pentanoate, ethyl-5-(2-fluoro-5-chlorothiophen-3-yl)pentanoate, ethyl-5-(2-fluoro-5-bromothiophen-3-yl)pentanoate, ethyl-5-(2-fluoro-5-iodothiophen-3-yl)pentanoate, ethyl-5-(2-chloro-5-bromothiophen-3-yl)pentanoate, ethyl-5-(2-chloro-5-iodothiophen-3-yl)pentanoate, ethyl-5-(2-bromo-5-chlorothiophen-3-yl)pentanoate, ethyl-5-(2-bromo-5-chlorothiophen-3-yl)pentanoate, ethyl-5-(2-bromo-5-iodothiophen-3-yl)pentanoate, ethyl-5-(2-iodo-5-chlorothiophen-3-yl)pentanoate, ethyl-5-(2-iodo-5-bromothiophen-3-yl)pentanoate, and ethyl-5-(2-iodo-5-fluorothiophen-3-yl)pentanoate. Preferably, the 2,5-dihalo-3-substituted-thiophene is 2-bromo-3-hexyl-5-iodothiophene or ethyl-5-(2-bromo-5-iodothiophen-3-yl)pentanoate.

Suitable 2,5-dihalo-3,4-disubstitutedthiophenes may include, for example, ethyl-5-(2-5-difluoro-3-hexylthiophen-3-yl)pentanoate, ethyl-5-(2-5-dichloro-3-hexylthiophen-3-yl)pentanoate, ethyl-5-(2-5-dibromo-3-hexylthiophen-3-yl)pentanoate, ethyl-5-(2-5-diiodo-3-hexylthiophen-3-yl)pentanoate, ethyl-5-(2-fluoro-5-chloro-3-hexylthiophen-3-yl)pentanoate, ethyl-5-(2-fluoro-5-bromo-3-hexylthiophen-3-yl)pentanoate, ethyl-5-(2-fluoro-3-hexyl-5-iodothiophen-3-yl)pentanoate, ethyl-5-(2-chloro-3-hexyl-5-fluorothiophen-3-yl)pentanoate, ethyl-5-(2-chloro-3-hexyl-5-bromothiophen-3-yl)pentanoate, ethyl-5-(2-chloro-3-hexyl-5-iodothiophen-3-yl)pentanoate, ethyl-5-(2-bromo-5-chloro-3-hexylthiophen-3-yl)pentanoate, ethyl-5-(2-bromo-3-hexyl-5-iodothiophen-3-yl)pentanoate, ethyl-5-(2-iodo-3-hexyl-5-chlorothiophen-3-yl)pentanoate, ethyl-5-(2-iodo-3-hexyl-5-bromothiophen-3-yl)pentanoate, and ethyl-5-(2-iodo-5-fluoro-3-hexylthiophen-3-yl)pentanoate.

### Solvents

The solvent employed in these methods can be aprotic organic solvents. One or multiple solvent compounds, or mixtures, can be used. Suitable solvents include ethereal or polyethereal solvents. Examples of such solvents include ethyl ether, methyl-t-butyl ether, tetrahydrofuran (THF), dioxane, diglyme, triglyme, 1,2-dimethoxyethane (DME or glyme), and the like. A typical solvent is tetrahydrofuran.

### Polymerization Catalysts

Many metal catalysts can be used in the polymerizations in these methods. The metal catalyst can comprise an organometallic compound or a transition metal complex. For example, the metal catalyst can be a nickel, platinum, or palladium compound. Preferably, the metal catalysts are nickel (II) catalysts and palladium(0) catalysts. The use of nickel (II) catalysts may afford, for example, regioselective polythiophenes whereas the use of palladium(0) catalysts may afford, for example, regiorandom polythiophenes.

The catalyst employed to form regioregular conducting polymers in the method of one embodiment is a Ni(II) catalyst. An effective amount of the Ni(II) catalyst is employed, such that a sufficient amount of catalyst is employed to effect the reaction in less than about 5 days. Typically, this is an amount of about 0.01-10 mole percent (mol %), however, any amount of the Nickel (II) catalyst can be employed, such as 50 mol %, 100 mol %, or more. Typically, about 0.1 mol % Nickel (II) catalyst to about 5 mol % Nickel (II) catalyst is employed, or preferably, about 0.1 mol % Nickel (II) catalyst to about 3 mol % Nickel (II) catalyst is employed, based on the amount of monomer present.

Examples of suitable nickel (II) catalysts include, for example, Ni(PR₃)₂X₂ wherein R is (C₁-C₂₀)alkyl, (C₆-C₂₀)aryl, and X is halo, NiLX₂ wherein L is a suitable nickel (II) ligand and X is halo. Suitable nickel (II) ligands include 1,2-bis(diphenylphosphino)ethane, 1,3-diphenylphosphinopropane, [2,2-dimethyl-1,3-dioxolane-4,5-diyl)bis(methylene)] diphenylphosphine, bis(triphenylphosphine), and (2,2′-dipyridine) ligands. Other suitable Ni(II) catalysts include Ni(CN)₄⁻², NiO, Ni(CN)₅⁻³, Ni₂Cl₈⁻⁴, NiF₂, NiCl₂, NiBr₂, NiI₂, NiAs, Ni(dmph)₂, wherein dmph is dimethylglyoximate, BaNiS, [NiX(QAS)]⁺ wherein X is halo and QAS is As(o-C₆H₄AsPh₂)₃, [NiP(CH₂CH₂CH₂AsMe₂)₃CN]⁺, [Ni(NCS)₆]⁻⁴, KNiX₃ wherein X is halo, [Ni(NH₃)₆]⁺², and [Ni(bipy)₃]⁺², wherein bipy is bipyridine.

Typical nickel catalysts also include 1,2-bis(diphenylphosphino)ethane nickel (II) chloride (Ni(dppe)Cl₂), 1,3-diphenylphosphinopropane nickel (II) chloride (Ni(dppp)Cl₂), 1,5-cyclooctadiene bis(triphenyl) nickel, dibromo bis(triphenylphosphine) nickel, dichoro(2,2′-dipyridine) nickel, and tetrakis(triphenylphosophine) nickel (0).

The catalyst typically employed to form regiorandom conducting polymers in the method of one embodiment is a palladium (0) (“Pd (0)”) catalyst. An effective amount of the Pd (0) catalyst is employed, such that a sufficient amount of catalyst is employed to effect the reaction in less than about 5 days. Typically, this is an amount of about 0.01-10 mole percent (mol %), however, any amount of the Pd (0) catalyst can be employed, such as 50 mol %, 100 mol %, or more. Typically, about 0.1 mol % Pd (0) catalyst to about 5 mol % Pd (0) catalyst is employed, or preferably, about 0.1 mol % Pd (0) catalyst to about 3 mol % Pd (0) catalyst is employed, based on the amount of monomer present.

The Pd (0) catalyst is preferably selected from a group consisting of a PdL₄, PdL₂L′₂, PdLL′₃, and Pd (L-L)₂ catalyst, wherein L and L′ are selected from the group consisting of PF₃, PPh₃, P(OR)₃ (wherein R is any aliphatic, aryl, or vinyl group), AsPh₃, CO, CN, PEtPh₂, PEt₂Ph, P(4-MeC₆H₄)₃, SbPh₃, CNR (wherein R is any aliphatic, aryl, or vinyl group), and R—C═C—R (wherein R is any aliphatic, aryl, or vinyl group), and wherein L-L is selected from the group consisting of cyclooctadiene, 1,2-bis(diphenylphosphino)ethane, 1,3-bis(diphenylphosphino)propane, and [(2,2-dimethyl-1,3-dioxolane-4,5-diyl)bis(methylene)] diphenylphosphine. For example, the Pd (0) catalyst can be Pd (PPh₃)₄, polymer-bound Pd (PPh₃)₄, Pd (PF₃)₄, Pd (PEtPh₂)₄, Pd (PEt₂Ph)₄, Pd[P(OR)₃]₄ (wherein R is any aliphatic, aryl, or vinyl group), Pd[P(4-MeC₆H₄)₃]₄, Pd (AsPh₃)₄, Pd (SbPh₃)₄, Pd (CO)₄, Pd (CN)₄, Pd (CNR)₄ (wherein R is any aliphatic, aryl, or vinyl group), Pd (R—C═C—R) (wherein R is any aliphatic, aryl, or vinyl group), Pd (PF₃)₂, Pd (dppe)₂, wherein dppe is 1,2-bis(diphenylphosphino)ethane, Pd (cod)₂, wherein cod is cyclooctadiene, Pd (dppp)₂, wherein dppp is 1,3-bis(diphenylphosphino)propane, bis[2,2-dimethyl-1,3-dioxolane-4,5-diyl)bis(methylene)]diphenylphosphine palladium, and bis(dibenzylideneacetone) palladium. More preferably, the Pd (0) catalyst is selected from the group consisting of Pd (PPh₃)₄, polymer-bound Pd (PPh₃)₄, Pd (dppe)₂, and Pd bis(dibenzylideneacetone). Most preferably, the Pd (0) catalyst is Pd (PPh₃)₄.

General techniques and methods known by those of ordinary skill in the art can be used in the methods herein, such as the various standard procedures for carrying out the polymerization, and for isolating and purifying the products.

### Polymer Structure and Properties of Conducting Polymers

Typically, conducting polymers are organic polymers that, due to their conjugated backbone structure, show high electrical conductivities under some conditions (relative to those of traditional polymeric materials). Performance of these materials as a conductor of holes or electrons is increased, when they are doped, oxidized, or reduced. Upon low oxidation (or reduction) of conducting polymers, in a process, which is frequently referred to as doping, an electron is removed from the top of the valence band (or added to the bottom of the conduction band) creating a radical cation (or polaron). Formation of a polaron creates a partial delocalization over several monomeric units. Upon further oxidation, another electron can be removed from a separate polymer segment, thus yielding two independent polarons. Alternatively, the unpaired electron can be removed to create a dication (or bipolaron). In an applied electric field, both polarons and bipolarons are mobile and can move along the polymer chain by delocalization of double and single bonds. This change in oxidation state results in the formation of new energy states, called bipolarons. The energy levels are accessible to some of the remaining electrons in the valence band, allowing the polymer to function as a conductor. The extent of this conjugated structure is dependent upon the polymer chains to form a planar conformation in the solid state. This is because conjugation from ring-to-ring is dependent upon π-orbital overlap. If a particular ring is twisted out of planarity, the overlap cannot occur and the conjugation band structure can be disrupted. Some minor twisting is not detrimental since the degree of overlap between, for example, thiophene rings varies as the cosine of the dihedral angle between them.

Performance of a conjugated polymer as an organic conductor can also be dependant upon the morphology of the polymer in the solid state. Electronic properties can be dependent upon the electrical connectivity and inter-chain charge transport between polymer chains. Pathways for charge transport can be along a polymer chain or between adjacent chains. Transport along a chain can be facilitated by a planar backbone conformation due to the dependence of the charge carrying moiety on the amount of double-bond character between the rings, an indicator of ring planarity. This conduction mechanism between chains can involve either a stacking of planar, polymer segment, called π-stacking, or an inter-chain hopping mechanism in which excitons or electrons can tunnel or “hop” through space or other matrix to another chain that is in proximity to the one that it is leaving. Therefore, a process that can drive ordering of polymer chains in the solid state can help to improve the performance of the conducting polymer. It is known that the absorbance characteristics of thin films of conducting polymers reflect the increased re-stacking, which occurs in the solid state.

To effectively use a conjugated polymer, it is advantageously prepared by a method that allows the removal of organic and ionic impurities from the polymeric matrix. The presence of impurities, notably metal ions, for example, in this material may have serious deleterious effects on the performance of the conducting polymer. These effects include, for example, charge localization or trapping, quenching of the exciton, reduction of charge mobility, interfacial morphology effects such as phase separation, and oxidation or reduction of the polymer into an uncharacterized conductive state, which may not be suitable for a particular application. There are several methods by which impurities may be removed from a conjugated polymer. Most of these are facilitated by the ability to dissolve the polymer in common organic and polar solvents.

The conducting polymers prepared by the methods described herein may be conducting homopolymers, conducting block copolymers, polythiophene block-copolymers, or block-copolymer that include one block of polythiophene and one block of another conducting polymer. Polymerization of polythiophenes and block copolymers for other types of non-thiophene polymers are described in, for example, Yokozawa et al., Polymer Journal, 36(2), 65 (2004). Block copolymers are generally known in the art. See, for example, Yang (Ed.), The Chemistry of Nanostructured Materials, pages 317-327 (“Block Copolymers in Nanotechnology”) (2003). Also block copolymers are described in, for example, Block Copolymers, Overview and Critical Survey, by Noshay and McGrath, Academic Press, 1977. For example, this text describes A-B diblock copolymers (chapter 5), A-B-A triblock copolymers (chapter 6), and -(AB)ₙ-multiblock copolymers (chapter 7), which can form the basis of block copolymer types in the present invention. Additional block copolymers including polythiophenes are described in, for example, Francois et al., Synth. Met., 69, 463-466 (1995), Yang et al., Macromolecules, 26, 1188-1190, (1993), Widawski et al., Nature, 369, 387-389 (1994), Jenekhe et al., Science, 279, 1903-1907 (1998), Wang et al., J. Am. Chem. Soc., 122, 6855-6861 (2000), Li et al., Macromolecules, 32, 3034-3044 (1999), and Hempenius et al., J Am. Chem. Soc., 120, 2798-2804 (1998).

Suitable examples of other conducting polymers for a block-copolymer that includes polythiophene and another conducting polymer include, for example, a poly(pyrrole) or a poly(pyrrole) derivative, a poly(aniline) or a poly(aniline) derivative, a poly(phenylene vinylene) or a poly(phenylene vinylene) derivative, a poly(thienylene vinylene) or a poly(thienylene vinylene) derivative, poly(bis-thienylene vinylene) or a poly(bis-thienylene vinylene) derivative, a poly(acetylene) or a poly(acetylene) derivative, a poly(fluorene) or a poly(fluorene) derivative, a poly(arylene) or a poly(arylene) derivative, or a poly(isothianaphthalene) or a poly(isothianaphthalene) derivative, as well as segments composed of polymers built from monomers such as CH₂CHAr, where Ar is any aryl or functionalized aryl group, isocyanates, ethylene oxides, conjugated dienes, CH₂CHR₁R (where R₁ is alkyl, aryl, or alkyl/aryl functionality and R is H, alkyl, Cl, Br, F, OH, ester, acid, or ether), lactam, lactone, siloxanes, and ATRP macroinitiators.

Derivatives of a conducting polymer can be modified polymers, such as a poly(3-substituted thiophene), which retain the backbone structure of a base polymer, but are modified structurally over the base polymer. Derivatives can be grouped together with the base polymer to form a related family of polymers. The derivatives generally retain properties such as electrical conductivity of the base polymer.

In addition, the conducting polymers that are block copolymers can comprise the conductive block, having conjugated structures which may or may not be doped, and the nonconductive block. The non-conductive block can include a variety of synthetic polymers including condensation, addition, and ring-opened polymers including for example, urethanes, polyamides, polyesters, polyethers, vinyl polymers, aromatic polymers, aliphatic polymers, heteroatom polymers, siloxanes, acrylates, methacrylates, phosphazene, silanes, and the like. Inorganic and organic polymers can be used as the non-conductive part.

If desired, the conducting polymers can be blended with other components including inorganic glasses and metals as well as other polymers including inorganic polymers and organic polymers, as well as other conducting polymers either of the same type (e.g., two polythiophene types) or of different type (e.g., a polythiophene with a nonpolythiophene). The block copolymer can be used as a compatibilizing agent.

### Poly(3-Substituted Thiophenes)

In a preferred embodiment, the conducting polymer is a poly(3-substituted thiophene). Various poly(3-substituted thiophenes) with alkyl, aryl, and alkyl-aryl substituents are soluble in common organic solvents such as toluene and xylene. These materials share a common conjugated π-electron band structure, similar to that of poly(thiophene) that make them suitable p-type conductors for electronic applications, but due to their solubility they are much easier to process and purify than poly(thiophene). These materials can be made as oligomer chains such as (3-alkylhiophene)ₙ, (3-arylthiophene)ₙ, or (3-alkyl/arylthiophene)ₙ in which n is the number of repeat units with a value of 2-10 for oligomers or as polymers in which n is 11-350 or higher, but for these materials, n most typically has a value of 50-200.

Adding a 3-substituent to the thiophene ring, however, makes the thiophene repeat unit asymmetrical. Polymerization of a 3-substituted thiophene by conventional methods results in 2,5′-couplings, but also in 2,2′- and 5,5′-couplings. The presence of 2,2′-couplings or a mixture of 2,5′-, 2,2′- and 5,5′-couplings results in steric interactions between 3-substituents on adjacent thiophene rings, which can create a torsional strain. The rings rotate out of a planarity, to another, more thermodynamically stable, conformation, which minimizes the steric interactions from such couplings. This new conformation can include structures where π-overlap is significantly reduced. This results in a reduction inn-overlap between adjacent rings, and if severe enough, the net conjugation length decreases and with it the conjugated band structure of the polymer. The combination of these effects impairs the performance of electronic devices made from these regio-randomly coupled poly(3-substituted thiophenes).

### Regioregular Poly(3-Substituted Thiophenes)

In another preferred embodiment, the conducting polymer is a regio-regular poly(3-substituted thiophene). Materials with superior π-conjugation, electrical communication, and solid state morphology can be prepared by using regiospecific chemical coupling methods that produce greater than 95% 2,5′-couplings of poly(3-substituted thiophenes) with alkyl substituents.

Like regio-random poly(3-substituted thiophenes) with alkyl, aryl, and alkyl/aryl substituents, regio-regular poly(3-substituted thiophenes) with alkyl, aryl, and alkyl/aryl substituents are soluble in common organic solvents and demonstrate enhanced processability in applications by deposition methods such as spin-coating, drop casting, dip coating, spraying, and printing techniques (such as ink-jetting, off-setting, and transfer-coating). Therefore, these materials can be better processed in large-area formats compared to regio-random poly(3-substituted thiophenes). Furthermore, because of the homogeneity of their 2,5′-ring-to-ring couplings, they exhibit evidence of substantial π-conjugation and high extinction coefficients for the absorption of visible light corresponding to the π-π*absorption for these materials. This absorption determines the quality of the conducting band structure, which may be utilized when a regioregular poly(3-substituted thiophene) with alkyl, aryl, or alkyl/aryl substituents is used in an organic electronic device and, therefore, determines the efficiency and performance of the device.

Another benefit of the regio-regularity of poly(3-substituted thiophenes) is that they can self-assemble in the solid state and form well-ordered structures. These structures tend to juxtapose thiophene rings systems through a π-stacking motif and allow for improved inter-chain charge transport through this bonding arrangement between separate polymers, enhancing the conductive properties compared to regio-random polymers. Therefore, one can recognize a morphological benefit to these materials.

As is the case with the use poly(thiophene) it has been shown that various poly(3-substituted thiophenes) with alkyl, aryl, and alkyl-aryl substituents are soluble in common organic solvents such as toluene and xylene. These materials share a common conjugated π-electron band structure, similar to that of poly(thiophene) that make them suitable p-type conductors for electronic applications, but due to their solubility they are much easier to process and purify than poly(thiophene). These materials can be made as oligomer chains such as (3-alkylhiophene)ₙ, (3-arylthiophene)ₙ, or (3-alkyl/arylthiophene)ₙ, in which n is the number of repeat units with a value of 2-10 or as polymers in which n is 11-350 or higher, but for these materials, n most typically has a value of 50-200.

### Substituent Effects

Since the electronic properties of a conducting polymer arise from the conjugated band structure of the polymer backbone, any factors that increase or decrease the electron density within the backbone n-structure directly affect the band gap and energy levels of the conducting polymer. Therefore, substituents that are attached to the backbone and contain electron withdrawing substituents will reduce the electron density of the conjugated backbone and deepen the HOMO of the polymer. Substituents that are attached to the backbone and contain electron releasing functionality will have the opposite effect. The nature of the effects of substitution is known to any skilled in the art and is well documented in general texts on organic chemistry (see, e.g., March, J., Advanced Organic Chemistry, Third Edition, John Wiley & Sons, New-York, Inc. 1985 and references incorporated therein). In both cases, the magnitude of the change in energy levels of the polymer depend upon the specific functionality of the substituent, the proximity or nature of attachment of the functionality to the conjugated backbone, as well as the presence of other functional characteristics within the polymer.

In the case of poly(3-alkyl thiophenes), the alkyl substituents that are typically included to increase solubility have an electron releasing effect, raising the HOMO of the polymer relative to that of poly(thiophene). It has been shown, for example, that a fluorine substituent either as a component of 3-substituent or as the 4-substituent of a poly(thiophene) will withdraw electrons from a poly(thiophene) homopolymer, lowering the HOMO of the conducting polymer. It can be seen that alkoxy substituents on the 3-position may be used to decrease the band gap of a regioregular poly(3-substituted thiophene). In each of these cases, the manipulation of the energy levels has been accomplished by modification of the backbone of a homopolymer. In many instances, it is desirable to incorporate a particular functionality into a conducting polymer to impart a specific property. For example, the alkyl substituent of a poly(3-hexyl-thiophene) is included to make the polymer soluble in common organic solvents. However, for an application in which a deep HOMO is required, this electron-releasing functionality actually imparts the opposite of the desired electronic effect.

Therefore, a flexible synthetic method through which electronic, optical, and physical properties of the conducting polymer may be balanced and tuned to offer a material that satisfies diverse performance requirements offers a real advantage in organic device development.

The conducting polymers prepared by the methods disclosed herein may include, for example, unsubstituted poly(thiophene), poly(3-substituted-thiophene), or poly(3,4-disubstituted-thiophene). These substituents can be any of the groups recited under the definition of substituents above. In one embodiment, the thiophene is a 3-substituted thiophene, wherein the substituent is an alkyl, alkylthio, alkylsilyl, or alkoxy group. The substituent can be optionally substituted with other functional groups, for example, and with out limitation, about one to about five esters, ketones, nitriles, amines, halogens, aryl groups, heterocyclyl groups, and heteroaryl groups. One or more of the carbon atoms of alkyl chain of the alkyl, alkylthio, alkylsilyl, or alkoxy group can also be exchanged by one or more heteroatoms, such as O, S, NP groups (wherein P is a substituent or a nitrogen protecting group), or combinations thereof.

It is often preferable to include substituents that improve the solubility of the polythiophene. Such substituents can preferably include groups that include at least about five or six carbon atoms, such as hexyl, hexoxy, hexylthio, and hexylsilyl groups. In another embodiment, it can be preferable that the substituent directly attached to the 3-position is a heteroatom, such as a sulfur, silicon, oxygen, or nitrogen atom. The heteroatoms can be substituted with other appropriate groups, such as are described above in the definition of substituted. Heteroatoms at the 3-position of the thiophenes can further enhance the conductivity of the polythiophene by, for example, allowing for delocalization of the aromatic electrons of the thiophene ring systems and/or allowing for improved packing and optimized microstructure of the polymer, leading to improved charge carrier mobility. In various embodiments, it can be preferable to separate an aryl, heteroaryl, or heterocyclyl substituent from the thiophene ring by one or more (e.g., one to ten, one to five, or one to three) methylene groups, optionally exchanged by one or more heteroatoms, for example, a polyethylene or polyethyleneimine group wherein the group includes about 2 to about 10 repeating units. Substituents at the 3-position of the thiophene monomer can improve the regioregularity of the product polythiophene by providing steric bulk that influences the regiochemistry of the polymerization.

The terminal groups (group at the 2- or 5-position of the terminal thiophene of the polymer) on the product polythiophene can be hydrogen or a halogen. The terminal group of the polythiophene can also be an alkyl or functionalized alkyl group, which can be provided for by quenching the polymerization with an organometallic species, such as an organo-zinc reagent.

The average weight molecular weight of the conducting polymers prepared by the methods described herein can be about 5,000 to about 200,000, preferably about 20,000 to about 80,000, and more preferably about 40,000 to about 60,000, as determined by GPC using a polystyrene standard in tetrahydrofuran. The polydispersity index (PDI) can be about 1 to about 2.5, or preferably about 1.1 to about 2.4, or more preferably about 1.2 to about 2.2.

The regioregularity of the conducting polymers prepared by using the nickel (II) catalysts are typically at least about 87% without any purification after work-up. Simple purification techniques, such as Soxhlet extraction with hexanes can improve the regioregularity to greater than about 94%, preferably greater than about 95%, more preferably greater than about 97%, yet more preferably greater than about 98%, or even more preferably greater than about 99%. The crude conducting polymer can be isolated after polymerization by precipitation in methanol followed by simple filtration of the precipitated polymer. The crude conducting polymer has superior properties relative to the crude products of the art.

Higher regioregularity results in higher conductivity of the conducting polymer. When doped, a regioregular conducting polymer, for example, a 3-substituted polythiophene can have a conductivity of about 1,000 seimens/cm, +/−about 400 seimens/cm. Regiorandom 3-substituted polythiophenes typically conduct at about 5-10 seimens/cm. Furthermore, undoped regioregular 3-substituted polythiophenes conduct at about 10⁻⁵ to about 10⁻⁶ seimens/cm (the semiconductor range), and undoped regiorandom polythiophenes conduct at about 10⁻⁹ seimens/cm.

One embodiment is also directed to the formation of regiorandom conducting polymer. As discussed above, regiorandom conducting polymers, for example, polythiophenes are obtained, when the metal catalyst is a Pd (0) catalyst. Regiorandom conducting polymer, for example, polythiophenes may be useful in applications that do not require high conductivities or in applications such as sensor devices.

### Doping

In a preferred embodiment, the conducting polymer can be oxidatively or reductively doped. The addition of the dopant results in an expansion of the extent of the conjugated π system in the individual polymer molecule. It is not necessary to extend the conjugated π system over the full extent of the molecule. It is necessary to sufficiently extend the π conjugated system of an individual molecule so that after the solvent is removed the π conjugated part of an individual molecule is adjacent to a part of the π conjugated part of an adjacent molecule. In the π conjugated system an electron is delocalized over the entire π conjugated bonds. These electrons are more loosely bond and are available for electrical conduction. When an electric field is applied, and electron can flow along an individual molecule and hop from one molecule to an adjacent molecule in a region where the π conjugated parts of the adjacent molecules overlap.

Doping can also be achieved electrochemically by confining the conducting polymers to an electrode surface and subjecting it to an oxidizing potential in an electrochemical cell.

Dopants that may be included in the conducting polymer matrix include, for example, iodine (I₂), bromine (Br₂), ferric chloride, and various arsenate or antimony salts. Other dopants may include, for example, various known onium salts, iodonium salts, borate salts, tosylate salts, triflate salts, and sulfonyloxyimides. The conducting polymers may be doped, for example, by dissolving the polymer in a suitable organic solvent and adding the dopant to the solution, followed by evaporation of the solvent. Many variations of this technique can be employed and such techniques are well known to those of skill in the art. See for example, U.S. Pat. No. 5,198,153, which is hereby incorporated by reference.

In a conductive thin-film application, the conductivity can range from about 1×10⁻⁸ S/cm to about 10⁴ S/cm, but most typically it is in the range of about 1 S/cm to about 500 S/cm. In the case of conducting polymers that are regio-regular poly(3-substituted thiophenes) in which the 3-substitutent is an alkyl, aryl, or alkyl/aryl moiety with an oxygen substitution in either the α- or β-position of the 3-substituent or a hetero atom in either the α- or β-position of the 3-substituent, the desirable characteristics of the conductive thin film are that they retain their conductivity for thousands of hours under normal use conditions and meet suitable device stress tests at elevated temperatures and/or humidity. This facilitates an operational range of robust charge mobility and allows the tuning of properties by controlling the amount and identity of the doping species and complements the ability to tune these properties by the tuning of the primary structure.

There are many oxidants, which may be used to tune conductive properties as described above. By controlling the amount of exposure of the dopant to the conducting polymer, the resulting conductive thin film can be controlled. Because of their high vapor pressure and solubility in organic solvents, halogens may be applied in the gas phase or in solution. Oxidation of the conducting polymer greatly reduces the solubility of the material relative to that of the neutral state. Nevertheless, various solutions may be prepared and coated onto devices.

Suitable dopants may also include, for example, iron trichloride, gold trichloride, arsenic pentafluoride, alkali metal salts of hypochlorite, protic acids such as benzenesulfonic acid and derivatives thereof, propionic acid, and other organic carboxylic and sulfonic acids, nitrosonium salts such as NOPF₆ or NOBF₄, or organic oxidants such as tetracyanoquinone, dichlorodicyanoquinone, and hypervalent iodine oxidants such as iodosylbenzene and iodobenzene diacetate. Conducting polymers may also be oxidized by the addition of a polymer that contains acid or oxidative functionality, for example, poly(styrene sulfonic acid).

The solvents used in adding the dopants are not particularly limited. One or multiple solvent compounds, or mixtures, can be used. Organic solvents can also be used. For example, ethers, esters, and alcohols can be used. Water can be used. Polar solvents can be used. Aprotic solvents can be used. Solvents having molecular weights of under 200, or under 100 g/mol can be used.

Suitable solvents for adding dopants include, for example, dimethyl formamide (DMF), dioxolane, methyl ethyl ketone, MIBK, ethylene glycol dimethyl ether, butonitrile, cyclopentanone, cyclohexanone, pyridine, chloroform, nitromethane, 2-nitromethane, trichloroethylene tetrachloroethylene, propylene carbonate, quinoline, cyclohexanone, 1,4-dioxolane, dimethyl sulfoxide (DMSO), nitrobenzene, chlorobenzene, and 1-methyl-2-pyrrolidinone.

### Other Components

In a preferred embodiment, the conducting polymers can also include one or more other suitable components such as, for example, sensitizers, stabilizers, inhibitors, chain-transfer agents, co-reacting monomers or oligomers, surface active compounds, lubricating agents, wetting agents, dispersing agents, hydrophobing agents, adhesive agents, flow improvers, diluents, colorants, dyes, pigments, or dopants. These optional components can be added to a conducting polymer composition by dissolving the conducting polymer in a suitable organic solvent and adding the component to the solution, followed by evaporation of the solvent. In certain embodiments, the conducting polymer are significantly useful as substantially pure polymers or as a doped polymers.

### Thin Films

In a preferred embodiment, the conductive polymer may be in the form of a film. Highly conductive thin films of soluble, conducting polymers are useful in a variety of applications, including, for example, many types of diodes. In their neutral or undoped form, soluble conducting polymers offer the ability to be applied by spin casting, drop casting, screening, ink-jetting, and standard printing techniques such as transfer or roll coating. Conductivity can be tuned from the neutral or semi-conductive state to a highly conductive state depending upon the amount of dopant added, making the material specifically suitable for a given application. Generally speaking, conductive films of doped conducting polymers can be made transparent in the visible region. This makes them suitable for use as transparent conductors. This combination of properties makes them suitable for use in electronic devices such as diodes and light emitting diodes.

Conducting polymers, in particular doped polythiophenes, have been shown to function suitably as positive charge carriers, also known as hole injection layers, in diodes as well as in light emitting diodes and solid-state lighting. This is a function of their facile oxidation as well as their stability in the doped state. A commercial example of this type of application is poly(3,4-ethylenedioxythiophene), which is available from H. C. Stark GmbH of Goslar, Germany. This material has limited applicability in that it is synthesized in an oxidized form, low in pH, and insoluble. It is available as an aqueous dispersion.

Performance of conductive thin films is gauged by evaluation of their high electrical conductivity value, good electrical performance, and high thermal stability. Conductivity is typically measured by: σ=I/(4.53 VW), where conductivity, σ, is measured in S/cm, I=current in amps, V=voltage, V, and W=film thickness in cm. Typically this value is measured by the standard, four point probe method, wherein current is passed between two electrodes and potential is measured through another pair of electrodes. Thickness can be determined by various methods such as SEM and profilometry.

The use of soluble conducting polymers, such as poly(3-alkylthiophenes), to build conductive layers or films offers in diodes several advantages such as ease of processability of materials and components during device production. In their neutral or undoped form, conducting polymers offer the ability to use spin casting, drop casting, screening, ink-jetting, and standard printing techniques such as transfer or roll coating to apply the conducting polymer layer. These methods allow for facile in-situ processing and precise control over the volume of conductive material applied. In general, methods can be used, which are used for printable or printed electronics. Microlithography and nanolithography methods can be used.

The use of conducting polymers, for example, regio-regular poly(3-heteroatomic substituted thiophenes) offer several advantages in this application. Paramount among these advantages is the ability to tune the conductivity of the device through control of the morphology of the film, the selection of oxidant used, and the amount of oxidant used. As these materials are formed in the neutral or undoped state, conductivity may be carefully tuned by the amount of oxidation. Another key benefit of the use of these materials compared to the use of other conducting polymers is the stability of the oxidized or “doped” conductive state of the poly(3-heteroatomic substituted thiophene). The selective solubility of these materials also allows for selective application and removal of films of these materials in devices.

In addition, electrically conducting polymers are described in The Encyclopedia of Polymer Science and Engineering, Wiley, 1990, pages 298-300, including polyacetylene, poly(p-phenylene), poly(p-phenylene sulfide), polypyrrole, and polythiophene. This reference also describes blending and copolymerization of polymers, including block copolymer formation.

The high purity conducting polymers prepared by the methods described herein can be used to form thin films. The thin films can be formed using standard methods known to those of skill in the art, such as spin coating, casting, dipping, ink jet coating, bar coating, roll coating, air knife coating, curtain coating, extrusion slot die coating, and the like, using a solution of a conducting polymer dissolved in a solvent. See for example U.S. Pat. Nos. 5,892,244, 6,337,102, 7,049,631, 7,037,767, 7,025,277, 7,053,401, and 7,057,339 for methods of preparing thin films and organic field effect transistors, which are hereby incorporated by reference.

In one embodiment, a thin film of conducting polymer may be formed, for example, by forming a Langmuir-Blodgett film of the polythiophene precursor, and converting the polythiophene precursor into a polythiophene. Likewise, a thin film may be formed, for example, by vapor depositing a polythiophene precursor, and converting the polythiophene precursor into a polythiophene.

In one embodiment, a thin film of conducting polymer may be formed, for example, by spin coating. A solution of the conducting polymer is placed on the substrate, which is rotated at high speed in order to spread the fluid by centrifugal force. The rotation of the substrate is continued while the fluid spins off the edges of the substrate, until the desired thickness of the film is achieved. The applied solvent is usually volatile, and simultaneously evaporates. Further, the higher the angular speed of spinning, the thinner the film will be produced. The thickness of the film also depends on the concentration of the solution and the solvent.

In one embodiment, a thin film of a conducting polymer may be formed, for example, by casting. Molten conducting polymer is introduced into a mould, allowed to solidify within the mould, cooled, and the mould disassembled to afford the thin film.

In one embodiment, a thin film of a conducting polymer may be formed, for example, by dip coating in which a substrate is immersed into a tank containing polythiophene, removing the substrate from the tank, and allowing it to drain. The coated substrate can be air-dried or baking.

In one embodiment, a thin film of a conducting polymer may be formed, for example, by ink jet coating in which a solution of polythiophene is ejected from a piezoelectric ink jet onto a substrate. The coated substrate can be air-dried or baking.

The thin films can have a wide range of thickness. A typical thin film is in the range of about 1 μm to about 1 mm. The thin film can include a coloring agent, a plasticizer, or a dopant. The conducting polymers can be electrically conductive, particularly when a dopant is included in the polymer matrix.

### Applications

The applications of the conducting polymers are not particularly limited but include optical, electronic, energy, biomaterials, semiconducting, electroluminescent, photovoltaic, LEDs, OLEDs, PLEDs, sensors, transistors, field effect transistors, batteries, flat screen displays, organic lighting, printed electronics, nonlinear optical materials, dimmable windows, RFID tags, fuel cells, triodes, rectifiers, and others. See, for example, Kraft et al., Angew. Chem. Int Ed., 37, 402-428 (1998). See, also, Shinar, Organic Light-Emitting Devices, Springer-Verlag, (2004). Hole-injection layers can be fabricated. Multilayer structures can be fabricated and thin film devices made. Thin films can be printed. Patterning can be carried out. Printing on consumer products can be carried out. Small transistors can be fabricated. In many applications, the composition is formulated to provide good solution processing and thin film formation. Blends with other polymers including conductive polymers can be prepared. The nanowire morphology of the block copolymers can be exploited in nanoscale fabrication. The following is a brief description of exemplary applications for the conducting polymers.

### Organic Light-Emitting Diodes

In one preferred embodiment, the conducting polymers prepared by the methods described herein may be used in, for example, an organic light-emitting diode. For example, regioregular polythiophenes, which can be employed in the manufacture of organic light-emitting diodes (OLEDs). Organic light-emitting diodes (OLEDs) are used in electronic applications or as backlight of, for example, liquid crystal displays. Common organic light-emitting diodes are fabricated using multilayer structures. An emission layer is generally sandwiched between one or more electron-transport and/or hole-transport layers. By applying an electric voltage, electrons and holes as charge carriers move towards the emission layer, where their recombination leads to the excitation and luminescence of the lumophore units contained in the emission layer. The conducting polymers may be employed in one or more of the charge transport layers and/or in the emission layer, corresponding to their electrical and/or optical properties. Furthermore, their use within the emission layer is especially advantageous, if the conducting polymers show electroluminescent properties themselves or comprise electroluminescent groups or compounds. In such case, luminescence can be obtained by injection of charge carriers into the conducting polymer itself. The selection, characterization as well as the processing of suitable monomeric, oligomeric, and polymeric compounds or materials for the use in OLEDs is generally known by a person skilled in the art (see, e.g., Meerholz, Synthetic Materials, 111-112, 31-34 (2000) and Alcala, J. Appl. Phys., 88, 7124-7128 (2000) and the literature cited therein).

According to another use, the conducting polymers, especially those showing photoluminescent properties, may be employed as materials of light sources, for example, of display devices such as described in European Patent Application Publication No. EP 0 889 350 A1 or by C. Weder et al., Science, 279, 835-837 (1998).

### Field Effect Transistors

In a preferred embodiment, the conducting polymers may also be used in, for example, field effect transistors (FETs). In a field effect transistor, an organic semiconductive material is arranged as a film between a gate-dielectric, a drain, and a source electrode (see, e.g., U.S. Pat. No. 5,892,244, PCT Patent Application Publication No. WO 00/79617, and U.S. Pat. No. 5,998,804). Due to the advantages associated with these materials, like low cost fabrication of large surfaces, preferred applications of these field effect transistors are, for example, integrated circuitry, thin film transistor (TFT) displays, and security applications.

In security applications, field effect transistors and other devices with semiconductive materials, like transistors or diodes, may be used for radio frequency identification (RFID) tags or security markings to authenticate and prevent counterfeiting of documents of value. Documents of value may include, for example, banknotes, credit cards, identification (ID) cards, passports, licenses, or any other product with monetary value (e.g., stamps, tickets, shares of stock, bonds, checks, and the like).

### Photovoltaic Cells

In a preferred embodiment, the conducting polymers may also be used in, for example, photovoltaic cells. A photovoltaic cell is an electrochemical device that converts electromagnetic radiation to electrical energy. Although not limited by theory, the conversion of electromagnetic radiation to electrical energy may be accomplished through a charge separation event, which occurs after absorption of a photon. This causes the creation of an excited state, which can be referred to as an exciton, in a p-type semiconductor, which is in intimate contact with an n-type semiconductor. Typically the semiconductor domains are sandwiched in one or more active layers between two electrodes, wherein at least one electrode is sufficiently transparent to allow for the passage of the photon. A photovoltaic cell can be used to charge batteries or operate electronic devices. It offers advantages to any electrical application, which is electrically driven by an electrical distribution grid, either as a replacement for a battery or as means to restore the charge on a battery which is used to power a device. Finally, it can be used to supplement power supplied on the electrical distribution grid or to replace power supplied from the electrical distribution grid.

The photovoltaic cells typically include at least four components, two of which are electrodes. One component is a transparent first electrode such as indium tin oxide coated onto plastic or glass which functions as a charge carrier. This component is typically the anode, and allows ambient light to enter the device. A second electrode can be made of a metal, for example, calcium or aluminum. In some cases, this metal may be coated onto a supporting surface such as a plastic, glass sheet, sapphire, aluminum nitride, quartz, or diamond. This second electrode also carries current. Between these electrodes are either discrete layers or a mixture of p- and n-type semiconductors, the third and fourth components. The p-type material can be called the primary light harvesting component or layer. This material absorbs a photon of a particular energy and generates a state in which an electron is promoted to an excited energy state, leaving a positive charge or “hole” in the ground state energy levels. This is known as exciton formation. The exciton diffuses to a junction between p-type and n-type material, creating a charge separation or dissociation of the exciton. The electron and “hole” charges are conducted through the n-type and p-type materials, respectively, to the electrodes. This results in the flow of electric current out of the cell. In addition to the conducting polymers described herein, the p-type semiconductor can also comprise conjugated polymers including, for example, mixtures or blends of materials including use of poly-phenylenevinylene (PPV) or poly (3-hexyl)thiophene (P3HT). The n-type component can comprise materials with a strong electron affinity including, for example, carbon fullerenes, titanium dioxide, cadmium selenium, and polymers and small molecules that are specifically designed to exhibit n-type behavior.

Performance of photovoltaic cells can be determined by measurement of the efficiency of conversion of light energy to electrochemical energy as measured by the quantum efficiency (number of photons effectively used divided by the number of photons absorbed) and by the peak output power generated by the cell (given by the product IₚₚVₚₚ, where Iₚₚ is the current and Vₚₚ is the voltage at peak power).

### Electroluminescent Devices

In one preferred embodiment, the conducting polymers may also be used as, for example, hole injection or hole transport layers in organic or polymer electroluminescent devices. The use of the conducting polymers in electroluminescent devices offers several desirable properties such as increased luminescence of the device, lower threshold voltage, longer lifetime, electron blocking, ease of processability of materials and components during device production, the ability to use spin casting, drop casting, ink-jetting, and other printing techniques to apply the hole injection or hole transport layer in electroluminescent devices, the ability to prepare more flexible electroluminescent devices, the ability to prepare low-weight electroluminescent devices, and the ability to prepare low-cost electroluminescent devices.

An electroluminescent device is a device that converts electric current to a photon flux. This is accomplished when an electron and a positive charge or “hole” meet in an electroluminescent material creating an excited state species or exciton which emits a photon when it decays to the ground state. The device is an efficient way to produce light at low voltage and minimal radiant heat. These devices currently find uses in many consumer electronics.

One example of an electroluminescent device includes four components. Two of these components are electrodes. The first component can be a transparent anode such as indium tin oxide, coated onto a plastic or glass substrate, which functions as a charge carrier and allows emission of the photon from the device. The second electrode, or cathode, is frequently made of a low work function metal such as calcium or aluminum or both. In some cases, this metal may be coated onto a supporting surface such as a plastic, glass sheet, sapphire, aluminum nitride, quartz, or diamond. This second electrode conducts or injects electrons into the device. Between these two electrodes are the electroluminescent layer and the hole injection or hole transport layer.

The third component is an electroluminescent layer material. The electroluminescent layer can comprise, for example, materials based on the conducting polymers, other conducting polymers, and organic-transition metal small molecule complexes. These materials are generally chosen for the efficiency with which they emit photons when an exciton relaxes to the ground state through fluorescence or phosphorescence and for the wavelength or color of the light that they emit through the transparent electrode.

The fourth component is an hole injection or hole transport layer material. The hole injection or hole transport layer is a conducting material that is able to transfer a positive charge or “hole” from the transparent anode to the electroluminescent layer, creating the exciton which in turn leads to light emission. The hole injection or hole transport layers are typically p-doped or oxidized conductive materials that are generally chosen for the facility with which they are able to transfer a positive charge to the electroluminescent layer and their overall efficiency.

Organic and polymer electroluminescent devices can take a variety of forms. Where the electroluminescent layer includes, for example, small molecules, typically vacuum deposited, the devices are commonly referred to as OLEDs (Organic Light Emitting Diodes). Where the electroluminescent layer includes, for example, electroluminescent polymers, typically solution processed and deposited, the devices are commonly referred to as PLEDs (Polymer Light Emitting Diodes). Some electroluminescent layers may not conveniently fit either description, such as mixtures of an electroluminescent material and a solid electrolyte to form a light-emitting electrochemical cell. Electroluminescent layers can be designed to emit white light (i.e., a balanced mixture of primary colors) either for white lighting applications or to be color filtered for a full-color display application. Electroluminescent layers can also be designed to emit specific colors, such as red, green, and blue, which can be combined to create the full spectrum of colors.

The light emitting diodes (LEDs) can be combined to make flat panel displays, either monochrome (single color) or full color (large number of colors typically created by combinations of red, green and blue). They may be passive matrix displays, where strips of anode material are deposited orthogonally to strips of cathode material with hole injection or hole transport layer and electroluminescent layers in between, such that current flowing through one anode and one cathode strip causes the intersection point to luminesce as a single pixel in a display. They may also be active matrix displays where transistors at each pixel control whether the individual pixel luminesces and how brightly. Active matrix displays can be either bottom emitting, where the light shines through or beside the transistor circuitry or top emitting where the light shines out in the opposite direction of the layers that contain the transistor circuitry.

### Other Diodes

In one preferred embodiment, the conducting polymers may also be used in, for example, diodes, which are not light emitting or photovoltaic. Diodes are described in, for example, Ben G. Streetman, Solid State Electronic Devices, 4^{th} Ed., 1995 (see, e.g., Chapters 5 and 6). This book describes, for example, fabrication of junctions and diodes. In one type of diode, a p-type material is placed against an n-type of material. Examples of semiconductor junction types of diodes include normal p-n diodes, gold doped diodes, Zener diodes, avalanche diodes, transient voltage suppression (TVS) diodes, light-emitting diodes (LEDs), photodiodes, Schottky diodes, snap diodes, Esaki or tunnel diodes, IMPATT diodes, TRAPATT diodes, BARITT diodes, and Gunn diodes. Other types of diodes include point contact diodes, [tube or valve diodes, gas discharge diodes, and varicap or varactor diodes. One skilled in the art can prepare non-light emitting and non-photovoltaic diodes.

These on-light emitting and non-photovoltaic diodes can be fabricated by methods known in the art. For example, a p-n junction can be fabricated by (i) providing a p-type material, (ii) providing an n-type material, and (iii) combining the p-type material and the n-type material so that they contact each other by methods known in the art. The p-type material can be the conducting polymers as described herein. Similarly, an additional step can be provided for providing an additional p-type material and combining it with the p-n junction to provide a p-n-p sandwich structure.

The conducting polymers can further be used in, for example, liquid crystal and/or semiconducting materials, devices, or applications. The increased conductance of these polymers compared to conventional syntheses allows for improved conductance, and therefore, improved function of these applications and devices.

The polymers described herein are also useful in, for example, reflective films, electrode materials in batteries, and the like. Accordingly, an electronic device including a circuit constructed with a polymer as described herein, such as a polymer prepared as described in Example 1 may also be useful.

The conducting polymers may be, for example, regiorandom polythiophenes, which can be employed in electronic device applications that do not require the high conductivities exhibited by regioregular polythiophenes. For example, the optical properties of the regiorandom polythiophene depend distinctly on the polycation and the pH of the solution, showing significant differences on visible absorption maxima of the assemblies ranging from 435 nm to 516 nm. (see, e.g., Myunghwan, et al., J. Macromol. Sci., 38(12), 1291 (2001)). This unusual sensitivity of regiorandom polythiophenes to polycations may have potential application in sensor devices.

It is to be understood that certain descriptions of the present invention have been simplified to illustrate only those elements and limitations that are relevant to a clear understanding of the present invention, while eliminating, for purposes of clarity, other elements. Those of ordinary skill in the art, upon considering the present description of the invention, will recognize that other elements and/or limitations may be desirable in order to implement the present invention. However, because such other elements and/or limitations may be readily ascertained by one of ordinary skill upon considering the present description of the invention, and are not necessary for a complete understanding of the present invention, a discussion of such elements and limitations is not provided herein. For example, the materials of the present invention may be incorporated in electronic devices that are understood by those of ordinary skill in the art, and accordingly, are not described in detail herein.

Furthermore, compositions of the present invention may be generally described and embodied in forms and applied to end uses that are not specifically and expressly described herein. For example, one skilled in the art will appreciate that the present invention may be incorporated into electronic devices other than those specifically identified herein. Other preferred embodiments may include devices that may be fabricated (depending on the properties of the present polymers) including, for example, unipolar transistors (e.g., FETs, BJTs, and JFETs), heterojunction transistors (e.g., HEMTs and HBTs), detectors (e.g., PIN, MSM, HPT, focal plane arrays, CCDs, and active pixel sensors), diodes (e.g., Peltier and piezoelectric), optical devices (e.g., waveguides, external cavity lasers & resonators, WGM lasers, optical amplifiers, and tunable emitters), and quantum structures (e.g., quantum wires, quantum dots, and nanowires).

### Methods of Making the Compositions

The compositions described herein can be prepared by any of the applicable techniques of organic synthesis. Many such techniques are well known in the art. However, many of the known techniques are elaborated in Compendium of Organic Synthetic Methods (John Wiley & Sons, New York) Vol. 1, Ian T. Harrison and Shuyen Harrison (1971); Vol. 2, Ian T. Harrison and Shuyen Harrison (1974); Vol. 3, Louis S. Hegedus and Leroy Wade (1977); Vol. 4, Leroy G. Wade Jr., (1980); Vol. 5, Leroy G. Wade Jr. (1984); and Vol. 6, Michael B. Smith; as well as March, J., Advanced Organic Chemistry, 3rd Edition, John Wiley & Sons, New York (1985); Comprehensive Organic Synthesis. Selectivity, Strategy & Efficiency in Modern Organic Chemistry, In 9 Volumes, Barry M. Trost, Editor-in-Chief, Pergamon Press, New York (1993); Advanced Organic Chemistry, Part B: Reactions and Synthesis, 4th Ed.; Carey and Sundberg; Kluwer Academic/Plenum Publishers: New York (2001); Advanced Organic Chemistry, Reactions, Mechanisms, and Structure, 2nd Edition, March, McGraw Hill (1977); Protecting Groups in Organic Synthesis, 2nd Edition, Greene, T. W., and Wutz, P. G. M., John Wiley & Sons, New York (1991); and Comprehensive Organic Transformations, 2nd Edition, Larock, R. C., John Wiley & Sons, New York (1999).

### EXAMPLES

The following Examples are illustrative of the above invention. One skilled in the art will readily recognize that the techniques and reagents described in the Examples suggest many other ways in which the present invention could be practiced. It should be understood that many variations and modifications may be made while remaining within the scope of the invention.

Other than in the operating examples, or unless otherwise expressly specified, all of the numerical ranges, amounts, values and percentages such as those for amounts of materials, times and temperatures of reaction, ratios of amounts, and others in the following portion of the specification may be read as if prefaced by the word “about” even though the term “about” may not expressly appear with the value, amount, or range. Accordingly, unless indicated to the contrary, the numerical parameters set forth in the following specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Furthermore, when numerical ranges of varying scope are set forth herein, it is contemplated that any combination of these values inclusive of the recited values may be used.

Reactions were typically carried out on a dual manifold vacuum/argon or nitrogen system. The handling of air-sensitive materials was performed under argon or nitrogen in a dry box when necessary. Chemical reagents were primarily purchased from Aldrich Chemical Co., Inc. (Milwaukee, Wis.), and were used as received unless indicated otherwise.

### Example 1

### Preparation of Regioregular HT Poly(3-hexylthiophene) from 2,5-Dibromo-3-hexylthiophene and alkyl Grignard in the Presence of Manganese Chloride

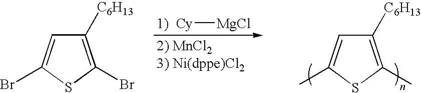

A 250 mL of round-bottom-flask was charged with 2,5-dibromo-3-hexylthiophene (8.15 grams (g), 25 mmol) and 50 mL of tetrahydrofuran. The reaction flask was cooled in an ice-bath. With stirring at 0° C., cyclohexylmagnesium chloride (2.0 M in ether, 12.5 mL, 25 mmol) was slowly added into the reaction flask. After being stirred at 0° C. for 10 minutes, manganese chloride (0.5 M in tetrahydrofuran, 50 mL, 25 mmol) was added to the reaction mixture, which was allowed to warm to room temperature over 20 minutes. Stirring was discontinued and solids settled to the bottom of the reaction vessel. Without transferring the solids, the reaction solution was cannulated to a flask containing Ni(dppe)Cl₂ (0.04 g, 0.3 mol %) in 10 mL of tetrahydrofuran at room temperature. The resulting mixture was stirred at room temperature for 24 hours. A dark-purple precipitate gradually formed over the course of the 24 hours. The entire mixture was then poured into 100 mL of methanol. The resulting dark precipitate was filtered, washed with methanol, and then dried under high vacuum.

The regioregularity of the polythiophene obtained was about 87%, as determined by ¹H NMR analysis.

The average weight molecular weight of the regioregular HT poly(3-substituted-thiophene) was about 40,000 to about 60,000 as determined by GPC using a polystyrene standard in tetrahydrofuran. Light-scatting analysis indicates the average weight molecular weight is much higher, in the range of about 80,000 to about 120,000.

### Example 2

### Preparation of Regioregular HT Poly(3-hexylthiophene) from 2,5-Dibromo-3-hexylthiophene and alkyl Grignard in the Presence of Manganese Chloride

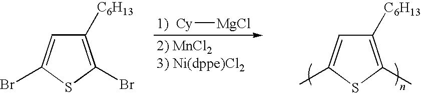

A 250 mL of round-bottom-flask was charged with 2,5-dibromo-3-hexylthiophene (8.15 g, 25 mmol) and 50 mL of tetrahydrofuran. The reaction flask was cooled in an ice-bath. With stirring at 0° C., cyclohexylmagnesium chloride (2.0 M in ether, 12.5 mL, 25 mmol) was slowly added into the reaction flask. After being stirred at 0° C. for 10 minutes, manganese chloride (0.5 M in tetrahydrofuran, 60 mL, 30 mmol) was added to the reaction mixture, which was allowed to warm to room temperature over 20 minutes. Stirring was discontinued and solids settled to the bottom of the reaction vessel. Without transferring the solids, the reaction solution was cannulated to a flask containing Ni(dppe)Cl₂ (0.04 g, 0.3 mol %) in 10 mL of tetrahydrofuran at room temperature. The resulting mixture was stirred at room temperature for 24 hours. A dark-purple precipitate gradually formed over the course of the 24 hours. The entire mixture was then poured into 100 mL of methanol. The resulting dark precipitate was filtered, washed with methanol, and then dried under high vacuum.

Similar results were obtained as in Example 1, with the exception that by employing 1.2 equivalents of MnCl₂, the regioregularity of the crude polymer increased to about 92%.

### Example 3

### Comparative Example

Poly(3-hexylthiophene) was prepared by the method as substantially described in U.S. Pat. No. 6,166,172 for the preparation of poly(3-dodecylthiophene). A sample of 2,5-dibromo-3-hexylthiophene was dissolved in tetrahydrofuran, methyl magnesium bromide (1.3 equivalent) was added, and the mixture was refluxed for six hours. The catalyst Ni(dppp)Cl₂ (1 mol %) was added and the solution was then refluxed for two hours. The crude poly(3-hexyl-thiophene) was isolated and was found to possess 89% HT couplings, as determined by ¹H NMR analysis (analysis and integration of the C-4 vinyl proton and the C-3 α-methylene protons). The purification procedure of Example 1 of the '172 patent (Soxhlet extraction with three different organic solvents) was not conducted in order to provide a direct comparison with the crude poly(3-hexylthiophene) prepared by the methods described herein.

As a comparison to the method described in the '172 patent, poly(3-hexylthiophene) was prepared by the method described in Example 1 above with the following variations. Cyclohexylmagnesium chloride and MnCl₂ (1.5 equivalent each) were employed and the polymerization was carried out starting at 0° C., and cooling bath was allowed to warm to room temperature. As in Example 1, 0.3 mol % of Ni(dppe)Cl₂ catalyst was employed. The crude poly(3-hexylthiophene) was isolated and was found to possess 92% HT couplings, as determined by ¹H NMR analysis.

By direct comparison of these two techniques, it was found that employing the manganese transmetallation technique afforded a poly(3-hexylthiophene) with an increased HT coupling of about 3%. This increased HT purity results in less time, solvent, energy, and expense required to purify the product for use in the various devices described herein.

### Examples 4-39

### Preparation of Regioregular HT Poly(3-hexylthiophene)

### A. Preparation of Thienylmanganese Chloride Reagents

To an oven-dried 250 mL round-bottomed flask was added 6.52 grams (20 mmol) 2,5-dibromo-3-hexylthiophene and 40 mL of tetrahydrofuran. The flask was cooled to 0° C. in an ice bath with stirring and 10 mL (20 mmol) isopropylmagnesium chloride (2.0 M in tetrahydrofuran) was added with a syringe. The mixture was stirred at 0° C. for 5 minutes to afford the thienyl-Grignard solution.

To another oven-dried 250 mL round-bottomed flask was added 2.8 grams (22 mmol) MnCl₂ and 40 mL of tetrahydrofuran and stirred at room temperature. To this was added via a cannula, the above thienyl-Grignard solution to obtain a gold-colored mixture. The solution was stirred at room temperature for twelve hours and allowed to settle overnight to afford a gold-colored liquid and a yellow precipitate (the thienylmanganese chloride reagent).

### B. Preparation of Thienylmanganese Bromide Reagents

MnBr₂ was substituted for MnCl₂ in the above procedure to afford the thienylmanganese bromide reagent.

C. Polymerization of Organomanganese Reagents with the Reverse-Addition Procedure (Addition of Ni(II) catalyst into the Organomanganese Solution)

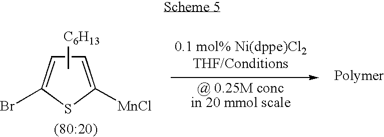

The thienylmanganese chloride prepared above was placed in an oven-dried 250 ml round-bottomed flask and cooled to 0° C. in an ice-bath. To this was added 0.1 gram (0.1 mol %) Ni(dppe)Cl₂ in one portion with a powder addition funnel. The mixture was stirred at 0° C. for 4-5 hours to form a polymer precipitate, warmed gradually to room temperature, and stirred at room temperature for an additional 19-20 hours. The mixture was poured into 80 ml methanol and stirred for 20 minutes. The polymer precipitate was filtered with a Buchner funnel, washed with methanol, and dried under a high vacuum to afford Examples 4-28 in Table 1.

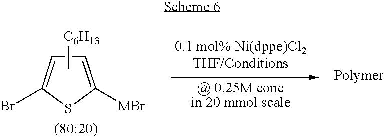

Examples 29-36 in Table 2 were also prepared with this procedure by substituting thienylmanganese bromide for thienylmanganese chloride.

D. Polymerization of Organomanganese Reagents with the Standard Addition Procedure (Addition of Organomanganese Solution into the Ni(II) catalyst)

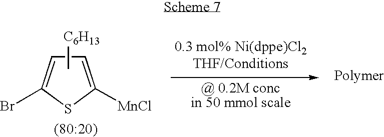

To a solution of 0.1 gram (0.1 mol %) Ni(dppe)Cl₂ in tetrahydrofuran was added the 0° C. solution of thienylmanganese chloride prepared above. The mixture was stirred at 0° C. for 4-5 hours to form a polymer precipitate, warmed gradually to room temperature, and stirred at room temperature for an additional 19-20 hours. The mixture was poured into 80 ml methanol and stirred for 20 minutes. The polymer precipitate was filtered with a Buchner funnel, washed with methanol, and dried under a high vacuum to afford Examples 29-31 in Table 3.

### E. Purification of Poly(thiophene)

A. Preparation of the L-Grade poly(thiophene).

The crude polymer was placed in a Soxhlet thimble and extracted with hexanes for 24 hours. The polymer was dried under high vacuum to afford Examples 4, 6, 8, 10-11, 13, 16, and 19-20 in Table 1.

B. Preparation of the 4002 Grade poly(thiophene).

The L-grade poly(thiophene) prepared above was placed in another Soxhlet thimble and extracted with chloroform until the polymer was removed from the thimble. The solution was concentrated under reduced pressure until polymer was observed on the wall of the flask. The residue was poured into approximately double the volume of hexanes with stirring. The polymer was filtered with a Buchner funnel, washed with hexanes, and dried under a high vacuum to afford Examples 6, 10, 15, 17, and 23 in Table 1.

C. Preparation of the E-Grade poly(thiophene).

The 4002 grade poly(thiophene) prepared above was placed in another Soxhlet thimble and extracted with chloroform until the polymer was removed from the thimble. The solution was concentrated under reduced pressure until polymer was observed on the wall of the flask. The residue was poured into methanol with stirring. The polymer was filtered with a Buchner funnel, washed with methanol, and dried under a high vacuum to afford Examples 10, 15, and 22 in Table 1.

TABLE 1
Reverse-Addition Procedure using Thienylmanganese Chloride

| | | | ¹H NMR Analysis | | | |
|---|---|---|---|---|---|---|
| | | Yield | | | | E- |
| Example | Conditions | (%) | Crude | L-grade | 4002 | grade |
| 4 | 0° C. for 6 hours | 40 | 95:5 | 97:3 | | |
| 5 | 0° C. for 6 hours with 10% | 39 | | | | |
| | TFT* | | | | | |
| 6 | 0° C. to 23° C. for 24 hours | 94 (78)** | 93:7 | 96:4 | 95:5 | |
| 7 | 0° C. to 23° C. for 24 hours | 82 | | | | |
| 8 | 0° C. to 23° C. for 24 hours | 73 (60) | | 97:3 | | |
| | with 10% TFT | | | | | |
| 9 | 0° C. to 23° C. for 24 hours | 48 | | | | |
| | with @ 0.5 M | | | | | |
| 10 | 0° C. to 23° C. for 24 hours | 66 (57) | 94:6 | 95:5 | 96:4 | 96:4 |
| | with @ 0.5 mol | | | | | |
| 11 | 23° C. for 24 hours | 64 | 82:18 | 94:6 | | |
| 12 | 23° C. for 24 hours | 76 | 91:9 | | | |
| 13 | 23° C. for 3 hours | 70 | 89:11 | 95:5*** | | |
| 14 | 23° C. for 3 hours/q.w/aq- | 61 | 92:8 | 95:5 and | | |
| | MeOH Solution | | | 95:5*** | | |
| 15 | 23° C. for 24 hours with 80 mmol | 65 (60) | 90:10 | | 97:3 | 96:4 |
| 16 | 23° C. for 24 hours with 0.1 M | 78 | 93:7 | 96:4 | | |
| 17 | 23° C. for 24 hours with 0.1 | 83 (74) | | | 94:6 | |
| | M and 80 mmol | | | | | |
| 18 | 23-36° C. for 24 hours | 73 | 92:8 | | | |
| 19 | 23° C. to reflux for 24 hours | 82 | 92:8 | 95:5 | | |
| 20 | 23° C. for 24 hours with | 6 | | | | |
| | NMP | | | | | |
| 21 | 23° C. for 24 hours with 10 mol | 73 (57 | | | | |
| | % TFT | | | | | |
| 22 | 23° C. for 24 hours with 10% | 91 (68) | | 95:5 | | |
| | TFT | | | | | |
| 23 | 23° C. for 24 hours with 10% | 65 (47) | | 92:8 | 93:7 | 94:6 |
| | TFT and 200 mmol | | | | | |
| 24 | 23° C. for 24 hours at 0.05 mol | 61 | 91:9 | | | |
| | % Ni | | | | | |
| 25 | Ni(PPh₃)₂Cl₂ | n/a**** | | | | |
| 26 | Ni(PMe₃)₂Cl₂ | n/a | | | | |
| 27 | Fe(dppe)Cl₂ | n/a | | | | |
| 28 | Co(dppe)Cl₂ | n/a | | | | |

*TFT = α,α,α-trinitrofluorotoluene
**= Soxhlet Extraction
***= simple washing
****n/a = not available

TABLE 2
Reverse-Addition Procedure using Thienylmanganese Bromide

| | | | ¹H NMR Analysis | | | |
|---|---|---|---|---|---|---|
| | | Yield | | L- | | E- |
| Example | Conditions | (%) | Crude | grade | 4002 | grade |
| 29 | 0° C. for 6 hours | 36 | 87:13 | | | |
| 30 | 0 to 23° C. for 24 hours | 56 | 90:10 | 96:4 | | |
| 31 | 23° C. for 24 hours | 51 | 89:11 | | | |
| 32 | 23° C. for 3 hours | 70 (55)** | | 96:4 | 95:5 | |
| 33 | 23° C. for 24 hours and 200 mmol | 55 (40) | | 93:7 | 93:7 | 94:6 |
| 34 | 23° C. for 24 hours and 0.05 mmol | 42 | | | | |
| | % Ni | | | | | |
| 35 | 23° C. for 24 hours and 10% | 64 (40) | | 94:6 | | |
| | TFT* | | | | | |
| 36 | Reflux for 24 hours | 55 (39) | | 94:6 | | |

*TFT = α,α,α-trinitrofluorotoluene
**= Soxhlet Extraction

TABLE 3
Standard Addition Procedure

| | | | ¹H NMR Analysis | | |
|---|---|---|---|---|---|
| Example | Conditions | Yield (%) | Crude | L-grade | 4002 |
| 37 | 0 to 23° C. for 24 | 72 | 92:8 | 95:5 | |
| | hours | | | | |
| 38 | 23° C. for 24 hours | 78 | | 92:8 | |
| 39 | 23° C. to reflux for | 63 | 85:15 | 87:13 | |
| | 24 hours | | | | |

The results in Tables 1-3 suggest that: a) a lower reaction temperature affords a higher regioregularity of the polymer (see, e.g., Table 1), b) the reverse addition procedure of Schemes 5-6 afford an easier work-up procedure; c) the thienyl-Grignard reagent may be prepared at either 0° C. or at room temperature to afford a 80:20 ratio at 0° C., d) a suspension of manganese halide in tetrahydrofuran was used because manganese halide was not totally soluble in tetrahydrofuran at room temperature, e) no big advantage was observed using manganese bromide instead of manganese chloride, the ratio of 5- and 2-thienylmanganese reagents was not a major factor in determining the regioregularity of the polymer, and g) the reverse addition procedure and lower reaction temperature are the preferred conditions for polymerization.

### Example 40

### Exemplary poly(3-substituted-thiophenes)

Scheme 7 illustrates several of the polythiophenes that can be prepared by the methods described herein, wherein n is a value such that the polythiophene polymer as a molecular weight of about 10,000 to about 200,000; “Hex” is hexyl but can be any alkyl group as described herein; “Bn” is benzyl which can be optionally substituted as described herein; “Ar” is aryl as described herein; “Het” is heteroaryl or heterocyclyl as described herein; m is 1 to about 20; and R is alkyl as described herein.

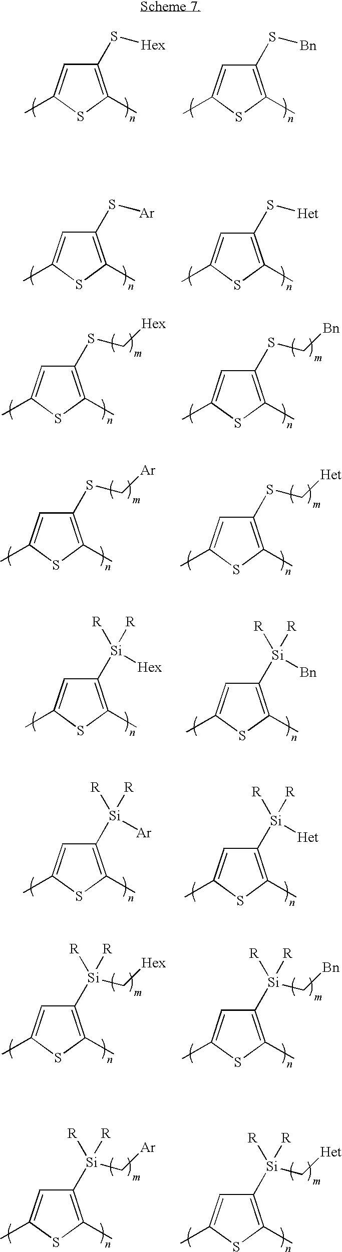

All publications, patents, and patent documents are incorporated by reference herein, as though individually incorporated by reference. The invention has been described with reference to various specific and preferred embodiments and techniques. However, it should be understood that many variations and modifications may be made while remaining within the spirit and scope of the invention.

1. A method of preparing a conductive polymer, comprising:
a) combining a first monomer-metal complex and an optional second monomer-metal complex together with a manganese (II) halide to provide a monomer-manganese complex, wherein each monomer-metal complex is prepared by combining a dihalo-monomer together with an organometallic reagent; and
b) combining the monomer-manganese complex together with a metal catalyst to provide the conductive polymer,
wherein each dihalo-monomer is independently an aromatic or heteroaromatic group substituted by two halogens wherein the halogens are the same or different, and
wherein halogen is F, Cl, Br, or I.

2. The method of claim 1, wherein the organometallic reagent is a Grignard reagent, a Grignard-ate complex, an alkyl lithium reagent, an alkyl lithium cuprate, an alkyl aluminum reagent, or an organozinc reagent, wherein the organozinc reagent is RZnX, R₂ZnX, or R₃ZnM, wherein R is (C₂-C₁₂) alkyl, M is magnesium, manganese, lithium, sodium, or potassium, and X is F, Cl, Br, or I.

3. The method of claim 1, wherein the metal catalyst and the monomer-manganese complex are combined in any order to provide the conducting polymer.

4. The method of claim 1, wherein the aromatic or heteroaromatic group is benzene, thiophene, pyrrole, furan, aniline, phenylene vinylene, thienylene vinylene, bis-thienylene vinylene, acetylene, fluorene, arylene, isothianaphthalene, p-phenylene sulfide, thieno[2,3-b]thiophene, thieno[2,3-c]thiophene, thieno[2,3-d]thiophene, naphthalene, benzo[2,3]thiophene, benzo[3,4]thiophene, biphenyl, or bithiophenyl, and
wherein the aromatic or heteroaromatic group has from zero to three substituents other than halogen.

5. The method of claim 4, wherein the zero to three substituents are each independently (C₁-C₂₄)alkyl, (C₁-C₂₄)alkylthio, (C₁-C₂₄)alkylsilyl, or (C₁-C₂₄)alkoxy that is optionally substituted with one to five ester, ketone, nitrile, amino, aryl, heteroaryl, or heterocyclyl groups, and one or more carbon atoms of the alkyl chain of the alkyl group are optionally exchanged by one to ten O, S, or NH groups, and
wherein the conducting polymer is a regioregular homopolymer, a regiorandom homopolymer, a regioregular copolymer, or a regiorandom copolymer.

6. The method of claim 1, wherein the conducting polymer is a homopolymer formed from the first dihalo-monomer or a copolymer formed from the first dihalo-monomer and the second dihalo-monomer.

7. The method of claim 1, wherein the conducting polymer is an unsubstituted polythiophene homopolymer, a poly(3-substituted-thiophene) homopolymer, a poly(3-substituted-thiophene) copolymer, a poly(3,4-disubstituted-thiophene) homopolymer, a poly(3,4-disubstituted-thiophene) copolymer, or a copolymer comprising unsubstituted thiophene, 3-substituted-thiophene, 3,4-disubstituted-thiophene, or a combination thereof.

8. The method of claim 1, wherein the manganese (II) halide is manganese fluoride, manganese chloride, manganese bromide, manganese iodide, or a combination thereof.

9. The method of claim 1, wherein the metal catalyst is a nickel (II) catalyst, wherein the nickel (II) catalyst is or is obtained from Ni(dppe)Cl₂, Ni(dppp)Cl₂, Ni(PPh₃)₂Br₂, 1,5-cyclooctadienebis(triphenyl)nickel, dichoro(2,2′-dipyridine)nickel, tetrakis(triphenylphosophine)nickel, NiO, NiF₂, NiCl₂, NiBr₂, NiI₂, NiAs, Ni(dmph)₂, BaNiS, or a combination thereof.

10. The method of claim 1, wherein the metal catalyst is a palladium(0) catalyst, wherein the palladium(0) catalyst is or is obtained from Pd (PPh₃)₄, polymer-bound Pd (PPh₃)₄, Pd (PF₃)₄, Pd (PEtPh₂)₄, Pd (PEt₂Ph)₄, Pd[P(OR)₃]₄, Pd[P(4-MeC₆H₄)₃]₄, Pd (AsPh₃)₄, Pd (SbPh₃)₄, Pd (CO)₄, Pd (CN)₄, Pd (CNR)₄, Pd (R—C═C—R), Pd (PF₃)₂, Pd (dppe)₂, Pd (cod)₂, Pd (dppp)₂, or a combination thereof, wherein R is any aliphatic, aryl, or vinyl group.

11. A method of preparing a conducting block copolymer comprising:
a) combining a metal catalyst together with a first monomer-manganese complex to provide a conducting block copolymer intermediate, wherein the first monomer-manganese complex is prepared by combining a first dihalo-monomer together with an organometallic reagent to provide a first monomer-metal complex, which is combined together with a manganese (II) halide;
b) combining a second monomer-manganese complex together with the conducting block copolymer intermediate to provide the conducting block copolymer, wherein the second monomer-manganese complex is prepared by combining a second dihalo-monomer together with an organometallic reagent to provide a second monomer-metal complex, which is combined together with a manganese (II) halide,
wherein each dihalo-monomer is independently an aromatic or heteroaromatic group substituted by two halogens wherein the halogens are the same or different,
wherein halogen is F, Cl, Br, or I, and
wherein if the first dihalo-monomer has the same ring system as the second dihalo-monomer, then at least one of the monomer-metal complexes is substituted, and if both of the monomer-metal complexes are substituted, then the substituents are not the same.

12. The method of claim 11, wherein the organometallic reagent is a Grignard reagent, a Grignard-ate complex, an alkyl lithium reagent, an alkyl lithium cuprate, an alkyl aluminum reagent, or an organozinc reagent, wherein the organozinc reagent is RZnX, R₂ZnX, or R₃ZnM, wherein R is (C₂-C₁₂) alkyl, M is magnesium, manganese, lithium, sodium, or potassium, and X is F, Cl, Br, or I.

13. The method of claim 11, wherein the aromatic or heteroaromatic group is benzene, thiophene, pyrrole, furan, aniline, phenylene vinylene, thienylene vinylene, bis-thienylene vinylene, acetylene, fluorene, arylene, isothianaphthalene, p-phenylene sulfide, thieno[2,3-b]thiophene, thieno[2,3-c]thiophene, thieno[2,3-d]thiophene, naphthalene, benzo[2,3]thiophene, benzo[3,4]thiophene, biphenyl, or bithiophenyl,
wherein the aromatic or heteroaromatic group has from zero to three substituents other than halogen.

14. The method of claim 12, wherein zero to three substituents are each independently (C₁-C₂₄)alkyl, (C₁-C₂₄)alkylthio, (C₁-C₂₄)alkylsilyl, or (C₁-C₂₄)alkoxy that is optionally substituted with one to five ester, ketone, nitrile, amino, aryl, heteroaryl, or heterocyclyl groups, and one or more carbon atoms of the alkyl chain of the alkyl group are optionally exchanged by one to ten O, S, or NH groups, and
wherein the conducting block copolymer is a regioregular block copolymer or regiorandom block copolymer.

15. The method of claim 11, wherein the first dihalo-monomer and the second dihalo-monomer are each independently selected from the group consisting of a 2,5-dihalo-thiophene, a 2,5-dihalo-pyrrole, a 2,5-dihalo-furan, a 1,3-dihalobenzene, a 2,5-dihalo-3-substituted-thiophene, a 2,5-dihalo-3-substituted-pyrrole, a 2,5-dihalo-3-substituted-furan, a 1,3-dihalo-2-substituted-benzene, a 1,3-dihalo-4-substituted-benzene, a 1,3-dihalo-5-substituted-benzene, a 1,3-dihalo-6-substituted-benzene, a 1,3-dihalo-2,4-disubstituted-benzene, a 1,3-dihalo-2,5-disubstituted-benzene, a 1,3-dihalo-2,6-disubstituted-benzene, a 1,3-dihalo-4,5-disubstituted-benzene, a 1,3-dihalo-4,6-disubstituted-benzene, a 1,3-dihalo-2,4,5-trisubstituted-benzene, a 1,3-dihalo-2,4,6-trisubstituted-benzene, a 1,3-dihalo-2,5,6-trisubstituted-benzene, a 1,4-dihalo-2-substituted-benzene, a 1,4-dihalo-3-substituted-benzene, a 1,4-dihalo-5-substituted-benzene, a 1,4-dihalo-6-substituted-benzene, a 1,4-dihalo-2,3-disubstituted-benzene, a 1,4-dihalo-2,5-disubstituted-benzene, a 1,4-dihalo-2,6-disubstituted-benzene, a 1,4-dihalo-3,5-disubstituted-benzene, a 1,4-dihalo-3,6-disubstituted-benzene, a 1,4-dihalo-3,5,6-trisubstituted-benzene, a 2,5-dihalo-3,4-disubstituted-thiophene, a 2,5-dihalo-3,4-disubstituted-pyrrole, a 2,5-dihalo-3,4-disubstituted-furan, and a combination thereof.

16. The method of claim 11, wherein the conducting block copolymer comprises unsubstituted thiophene, 3-substituted-thiophene, 3,4-disubstituted-thiophene, or a combination thereof.

17. The method of claim 11, wherein the manganese halide is manganese fluoride, manganese chloride, manganese bromide, manganese iodide, or a combination thereof.

18. The method of claim 10, wherein the metal catalyst is a nickel (II) catalyst, wherein the nickel (II) catalyst is or is obtained from Ni(dppe)Cl₂, Ni(dppp)Cl₂, Ni(PPh₃)₂Br₂, 1,5-cyclooctadienebis(triphenyl)nickel, dichoro(2,2′-dipyridine)nickel, tetrakis(triphenylphosophine)nickel, NiO, NiF₂, NiCl₂, NiBr₂, NiI₂, NiAs, Ni(dmph)₂, BaNiS, or a combination thereof.

19. The method of claim 10, wherein the metal catalyst is a palladium(0) catalyst, wherein the palladium(0) catalyst is or is obtained from Pd (PPh₃)₄, polymer-bound Pd (PPh₃)₄, Pd (PF₃)₄, Pd (PEtPh₂)₄, Pd (PEt₂Ph)₄, Pd[P(OR)₃]₄, Pd[P(4-MeC₆H₄)₃]₄, Pd (AsPh₃)₄, Pd (SbPh₃)₄, Pd (CO)₄, Pd (CN)₄, Pd (CNR)₄, Pd (R—C═C—R), Pd (PF₃)₂, Pd (dppe)₂, Pd (cod)₂, Pd (dppp)₂, or a combination thereof, wherein R is any aliphatic, aryl, or vinyl group.

20. A method of preparing a regioregular HT poly(thiophene) comprising combining a nickel (II) catalyst together with a thiophene-magnesium complex to provide a regioregular HT poly(thiophene), wherein the thiophene-magnesium complex is prepared by a method comprising contacting a 2,5-dihalo-thiophene metal complex with a magnesium halide.

21. An electronic device comprising a circuit constructed with a conducting polymer, a conducting block copolymer, or a regioregular HT poly(thiophene) prepared by the method of claim 1.

22. The electronic device of claim 21, wherein the device is a thin film transistor, a field effect transistor, a radio frequency identification tag, a flat panel display, a photovoltaic device, an electroluminescent display device, a sensor device, and electrophotographic device, or an organic light emitting diode.

23. A conducting polymer, a conducting block copolymer, or a regioregular HT poly(thiophene) prepared by the method of claim 1, having a regioregularity of at least about 87%.

24. The conducting polymer, the conducting block copolymer, or the regioregular HT poly(thiophene) of claim 23, having a form of a thin film.

25. A conducting polymer, a conducting block copolymer, or a regioregular HT poly(thiophene), having at least about 92% regioregularity; an average weight molecular weight of about 30,000 to about 70,000; and a conductance of about 10⁻⁵ to about 10⁻⁶ seimens/cm.
